(19) United States
(12) Patent Application Publication
(10) Pub. No.: US 2007/0133017 A1
(43) Pub. Date: Jun. 14, 2007

(54) Image processing apparatus, photographing apparatus, image processing system, image processing method and program

(76) Inventor: Hideyuki Kobayashi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/588,789

(22) PCT Filed: Jan. 26, 2005
(86) PCT No.: PCT/JP05/00969

§ 371 Date: Aug. 9, 2006

(30) Foreign Application Priority Data
Feb. 12, 2004 (JP) 2004-035160

(51) Int. Cl. G03F 3/08

(52) U.S. Cl. 358/1.9; 358/402; 358/518

(57) ABSTRACT

An image processing apparatus including an image processing section which conducts image processing on image data, wherein the image processing section compresses a hue reproduction angle in a range of flesh color area corresponding to a flesh color in the image data.

### FIELD OF THE INVENTION

The present invention relates to an image processing apparatus, a photographing apparatus, an image processing system, an image processing method and a program.

### DESCRIPTION OF RELATED ART

In development of digital photography, for reproducing a photographed image exactly, fundamentals are placed on colorimetric reproduction, where image processing is carried out to emphasize the contrast, lightness and chroma so that a preferable digital image may be obtained. A digital image based on the colorimetric reproduction has high color reproducibility including hue reproduction, and it is generally recognized to have bright finish in appearance for a scenic image and a still object image, resulting in spread on the market.

On the other hand, in addition to digital photographs which have recently grown rapidly, there are conventional photosensitive materials called recording materials for analogue photography, as photosensitive materials include a negative film, a positive reversal film and a photographic paper. For development of analogue recording materials, it is known that for realizing three-dimensional appearance and coloring of an image, a photosensitive layer is designed so that a development inhibiting effect that is called an inter-image effect from other color photosensitive layer may be less in cases where a photosensitive material is exposed to chromatic color light than in cases where it is exposes by achromatic white light, resulting in that chroma and contrast are reproduced to be higher on an area corresponding to chromatic color object than that on an area corresponding to an photographic object having a color that is close to achromatic color. It is further known that accurate hue reproduction in broad spectral sensitivity is difficult.

However, when considering images including persons as a photographic object, it was clarified that a human being has an extreme high distinctiveness for a flesh color of a person, and an expected value exists clearly, while in basic colorimetric reproduction such as those photographed on a digital basis, there is a problem. For example, in the case of images (portrait photographs, in general) such as a photograph of children, a photograph of wedding and an identity photograph which are used often for photographing of persons, it was clarified that an electronic flash is actually used to be a main light source, but, an ambient light source actually reaches a shadow area where electronic flash light does not reach to affect, whereby, hue deviation caused by other light sources tends to occur, and electronic flash light that advances straight, even when it is dispersed, tends to form a shadow, thus, its chroma is lower than that of an imagined image of a person photographed actually by ordinary light, resulting in an image which is unsuitable for portrait photographing and is unacceptable for viewing.

Further, it has come to understand that, if each of chromatic color and achromatic color has the same reproducibility, namely, the same contrast, images are felt to be flat to the human eyes, resulting in an extremely poor photograph that lacks a three-dimensional appearance. In this way, with respect to image quality of a digital image, colorimetric reproduction and reproduction of image with high image quality are in the relationship to conflict with each other.

There is further disclosed an image processing wherein image transform is carried out for data on portions other than a flesh color area under a viewpoint that image processes such as chroma processing and hue processing for the specific flesh color area are not preferable (for example, see Patent Document 1).

There is further proposed to maintain a profile of input equipment and a profile of target film to be outputted, then, to prepare a table for bringing color reproducibility of inputted image data close to color reproducibility of target film to be outputted based on the aforesaid profiles and to conduct color correction for contrast and highlight for the image data (for example, see Patent Document 2).

(Patent Document 1) Unexamined Japanese Patent Application Publication No. 2002-33934

(Patent Document 2) Unexamined Japanese Patent Application Publication No. 2000-50097

However, in the structure to conduct image transform for data of the portion other than a flesh color area as in the structure described in the Patent Document 1, image quality therefrom is insufficient as portrait photography, and its improvement is desired.

With respect to the output, a color reproducing technology to reproduce a color expressed on the monitor of a computer by using coloring materials actually is important, with the spread of digital images. For example, in the case of DTP, preparation, editing and processing for a color image are conducted on the color monitor, and the image is outputted by a color printer. Therefore, it is strongly desired that a color of an image displayed on the color monitor (hereinafter called “monitor image”) agrees perceptually with a color of an image outputted as a print (hereinafter called “print image”).

A color monitor on which a digital image is displayed employs additive color mixture that expresses a color image by using light having a specific wavelength emitted by, for example, a phosphor. On the other hand, when digital images are outputted, those outputted absorb light having a specific wavelength, and remaining reflected light expresses a color image, which is subtractive color mixture. Since the color expressing methods are different as stated above, if both are compared, they are greatly different in terms of color reproduction area, and reproduction is especially different between an area of low lightness and an area of high lightness, which is a problem.

Further, even in the case of the same color monitor, the one employing a liquid crystal panel, the one employing a cathode ray tube of an electron gun type and the one employing a plasma panel are different respectively in terms of a color reproduction area. In the case of a color printer again, though there are available a laser printer capable of outputting on a color paper representing analogue photosensitive material, and an ink-jet printer that outputs by using ink, where their color reproduction areas are different each other because coloring materials absorb light differently. Therefore, for the monitor images, print images and print images outputted by plural types of apparatuses or on plural types of sheets, it is impossible to make these image colors to be exactly the same each other in a colorimetric means, and these print images are insufficient because, when they are compared with real analogue photographs wherein input to output in analogue type are reproduced by the subtractive color mixture, they have neither similar three-dimensional appearance nor massive feeling.

Further, when perceptive agreement of colors between the monitor image and the print image is tried to be achieved, it is accompanied by a difficulty. The reasons of this difficulty are as follows. As a technology to eliminate a perceptive difference of colors between output media each having a different color reproduction area, and thereby to achieve perceptive agreement of colors of images to be formed, there exists gamut mapping that maps a certain color reproduction area to another color reproduction area by using a uniform color system. The gamut mapping is one that conducts linear mapping in lightness and chroma dimension for each hue, for example, in the uniform color system. However, even in the case of the digital image that has been subjected to the aforesaid image processing, a color reproduction area which has been mapped from the color reproduction area of the monitor to the color reproduction area of the printer by the gamut mapping is narrower than the color reproduction area of the printer. Therefore, the image to be outputted after being corrected by the gamut mapping is problematic because its contrast is low and it lacks brightness, and it has no massive feeling when it is compared with an analogue photograph.

Further, in the case of the structure in which image data are corrected in terms of color based on a profile of an input equipment and on a profile of a target film to be outputted, as in the structure described in Patent Document 2, a highlight on the reflection outputted object is felt to be of extremely high contrast in the human luminosity which is actually for transmission output. Therefore, it has come to be understood that the image is not observed to be in the optimum silver halide tone and is uncomfortable for viewing, unless contrast and lightness in the highlight area are changed between image data for outputting on transmission-type positive film or on CRT and image data for outputting on reflection type color paper.

As stated above, the digital image of a portrait photograph has been one which is not useful in the imaging market, and naturally in the photographic market, because hue tends to be fluctuated, chroma is quiet, and expected flesh color is not obtained stably and a finished photograph is planar, with the known image processing technology, compared with analogue photographs.

Further, in the image that is corrected by the known gamut mapping to be outputted as a print, it is generally impossible to output a print having both three-dimensional appearance and substantial feeling identical to those of analogue image, and digital image subjected to the aforesaid image processing cannot be used satisfactorily, resulting in the image that cannot meet the demands of the market.

### SUMMARY

The present invention is one to solve the aforesaid problems, and an object is to achieve appropriate color reproduction by conducting image processing on image data.

Specifically, the object is to transform to image data capable of obtaining output image wherein hue deviation for flesh color hardly occur when photographing for portrait photo, expected color is reproduced stably, further, chroma on the circumference shadow area is high and fine, three-dimensional appearance can be given, then, further, high quality image processed in the aforementioned manner can be outputted in an optimum manner, and both three-dimensional appearance and massive feeling identical to those of conventional analogue image are contained. Further object is to generate image data for output of transmission-type positive film or for output of CRT and optimum image data which cause no problem when they are outputted on a reflection type color paper.

An embodiment of the invention for attaining the aforesaid object is an image processing apparatus equipped with an image processing section that conducts image processing on image data wherein the image processing section compresses a hue reproduction angle in a range of flesh color area corresponding to flesh color in image data.

### BRIEF DESCRIPTION OF THE DRAWINGS

These and other objects, advantages and features of the invention will become apparent from the following description thereof taken in conjunction with the accompanying drawings in which:

FIG. 1 is an outline drawing of image forming apparatus 1 of the first embodiment relating to the invention;

FIG. 2 is a diagram showing a schematic structure of the image forming apparatus 1;

FIG. 3 is a diagram showing a schematic structure of image processing section 70;

FIG. 4 is a diagram showing a schematic structure of color reproduction transform section 7b;

FIG. 5 is a flow chart showing image adjustment processing;

FIG. 6 is a graph showing an example of linear hue compression;

FIG. 7 is a graph showing an example of nonlinear hue compression;

FIG. 8 is a graph showing an example of relationship of contrast (bit) between before transform and after transform with respect to achromatic color and chromatic color;

FIG. 9 is a graph showing an example of relationship of contrast (lightness) between before transform and after transform with respect to achromatic color and chromatic color;

FIG. 10 is a graph showing an example of chroma transform;

FIG. 11 is a graph showing an example of a lightness curve (contrast);

FIG. 12 is a graph showing a comparative example of gamut mapping;

FIG. 13 is a graph showing an example of gamut mapping;

FIG. 14 is a diagram showing an internal structure of digital camera 1α of the second embodiment relating to the invention;

FIG. 15 shows an internal structure of image processing system 2α of the third embodiment relating to the invention; and

FIG. 16 is a flow chart showing image processing.

### DETAILED DESCRIPTION OF THE PREFERRED EMBODIMENTS

The aforesaid objects are attained by the following structures.

(Structure 1)

An image processing apparatus equipped with an image processing section that conducts image processing for image data wherein the image processing section compresses hue reproduction angle in a range of flesh color area corresponding to a flesh color in image data.

Incidentally, image data to be subjected to image processing may either be image data obtained by taking an image for a photographic object with a digital still camera, for example, or be image data generated by a computer. Or, the image data may be those of each frame in the case of generating motion picture by rendering to a two-dimensional flat image after preparing a 3D stereoscopic image with each object, in which an animation may be prepared by connecting to the motion picture after transforming a certain amount of the image data. The image data may further be those obtained by illuminating a photographic film on which an image is recorded with light, and thereby, by transforming transmitted light into an electric signal with a photoelectric converter. As an outputting form for image data after image processing, there are given, for example, recording on a recording material such as a photographic paper and displaying on a device such as a display.

Further, with respect to hue reproduction, it can be obtained based on a relation between the color value on the original image data and the color value on the image data after passing through the processing wherein, for example: a relation between a color value on image data, or a value a. color expressed by using a similar and optional calorimetric system and a color value on a visible image in the case of outputting the visible image by using the image data is obtained; the color value on the original image data is transformed to a color value on the visible image based on the aforesaid relation; a certain amount of hue is changed for the color value on the visible image after transformation; the color value after being changed is inversely transformed to a color value on the image data based on the aforesaid relation; and then the color value on the image data corresponding to the visible image whose hue is changed by a prescribed amount is obtained.

In addition, image processing may also be carried out by the use of transformation data. For example, as transformation data to be stored in a memory means, it is possible to use, for example, data that correlate the color value after change of hue to those before the change when the color value is changed on the image data so that the hue on the visible image may be changed. For example, it is also possible either to store the color value itself as transformation data or to store the function indicating transformation characteristics as transformation data.

As a flesh color area, a flesh color is indicated on a visible image, which is a color area where image quality of the visible image is improved when a hue reproduction angle is compressed, and hue angle H* ranging from 0° to 90° is preferable, and hue angle H* ranging from 30° to 70° is especially preferable. By compressing the hue on the portion corresponding to the human skin on the visible image, it is possible to restrain hue changes under environmental light, and to restrain effectively partial decline of image quality.

It is possible to prescribe a given color area to be an area where, for example, a hue angle is within a prescribed range on the visible image. Hue angle H* is defined by the following expression (1) when a color on the visible image is expressed with colorimetric system L*a*b* recommended as a uniform perceptual color space by CIE (Commission Internationale del 'Eclairage: International Illumination Committee).
H*=tan⁻¹(b*/a*)·180/π (1)
(Structure 2)

The image processing apparatus according to the (Structure 1) above, wherein the image processing section compresses the hue reproduction angle in a range of flesh color area such that the range of flesh color area is converged to a target hue reproduction angle specified as a target.

When a target hue reproduction angle is made to be about 50°, for example, as a target hue reproduction angle, hue deviation of flesh color caused by hue compression which is generally preferable can be restrained, and by setting the target hue reproduction angle to be in the negative direction from 50°, namely, to +magenta in terms of hue, and by setting the target hue reproduction angle to be in the positive direction from 50°, namely, to +yellow in terms of hue, colors preferable for Japanese people and colors preferable for Western people can be set simply, and stable finish can be obtained.

(Structure 3)

The image processing apparatus according to (Structure 1) or (Structure 2), wherein the image processing section changes a center of a compressed hue reproduction angle in a range of the flesh color area and/or an amount of compression, based on color temperature and white point of illumination light at image data generation.

When color balance such as color temperature or a white point is different, processing is conducted by changing a center of hue compression and/or an amount of compression in a flesh color area, based on the condition of the aforesaid difference. Thereby, effects of the invention, hue stabilization, can be preferably exhibited to a maximum extent, even in the case of images of preferable color temperature for Japanese, bluish images, cool portrait images, and yellowish and warm color images which are said to be preferable for European/American peoples.

(Structure 4)

The image processing apparatus according to the Structure 1-Structure 3, wherein the image processing section makes degree of the compression of the hue reproduction angle to be enhanced as the angle recedes from the target hue reproduction angle, in the case of converging a range of the flesh color area to a target hue reproduction angle determined specifically.

When the extent of compression of the hue reproduction angle is made to be greater as the hue reproduction area goes away from the target hue reproduction angle, when converging a range of the flesh color area to the target hue reproduction angle, a tone jump hardly occurs when compressing the flesh color while suppressing hue changes of the flesh color, which is preferable. It is further preferable that an amount of compression increases depending on an angle difference from the target angle, and it increases following an S-shaped curve (cubic curve).

(Structure 5)

The image processing apparatus according to the Structure 1-Structure 4, wherein, the image processing section makes an extent of compression of the hue reproduction angle to be smaller as the chroma becomes higher.

When the extent of compression of the hue reproduction angle is made to be smaller as the chroma is elevated to be higher, reproduction of red color other than the flesh color is not obstructed, and deterioration is less, which is preferable. It is further preferable that an amount of hue reproduction change decreases mainly in a range of “chroma C* =0−30”, and it decreases following an S-shaped curve (cubic curve). The chroma C* is defined by the following expression (2), when a color on a visible image is expressed by colorimetric system L* a* b* recommended by CIE as a uniform perceived color space.
C*=(a*²+b*²)^{1/2} (2)

Under the condition where a prescribed color area is made to be a range of a flesh color area, by compressing the hue of a portion corresponding to the human skin on a visible image, it is possible to suppress hue changes under environmental light, and to suppress effectively a partial decline of image quality caused by the change of hue on a visible image, thus, an image free from problems can be obtained.

As a method for measuring contrast for a camera, it is possible to measure by photographing a gray chart for the neutral, for example, and by photographing a hue range of 5R-5YR of Munsell chart for the chromatic color. As a transform method, image data are prepared and are subjected to image processing, and the image data are measured and color values therefrom are used for the measurement.

(Structure 6)

An image processing apparatus equipped with an image processing section that conducts image processing for image data, wherein the image processing section makes contrast of neutral color image data to be low contrast and makes contrast of other chromatic colors to be high contrast.

If the chroma C* is made to be in a range of 15 or more, preferably to be in a range of 10 or more for chromatic colors; and the chroma is made to be in a color range of 15 or less, preferably to be in a color range of 10 or less for neutral color, color deviation in shadow balance of image processing and noises are reduced, which is preferable.

By making contrast of chromatic colors to be high contrast and making contrast of the neutral color to be low contrast after image processing, it is possible to obtain an effect of image quality improvement to acquire three-dimensional feeling by optical illusion that is preferable for a portrait. Contrast is defined with 60-170 bit when, for example, it is expressed at L* 25-70 and is observed with RGB signal values. It is further preferable to make contrast of chromatic colors to be 1.03 or more and to make contrast of neutral to be 0.97, after image processing.

(Structure 7)

The image processing apparatus according to the Structure 6, wherein the image processing section makes a difference between the contrast of a chromatic color of the image data and the contrast with neutral to be 5% or more.

When the contrast difference between the chromatic color and the neutral representing (chromatic color-neutral)/(neutral) is made to be 5% or more, the three-dimensional feeling is clearly improved, which is preferable. In particular, the contrast difference between the chromatic color and the neutral which is made to be 10% or more is preferable from the viewpoint of the three-dimensional feeling and presentation of the neutral of highlight. In addition, S-shaped form of the contrast curve of the chromatic color makes it easy to obtain three-dimensional feeling especially on the contour portion, which is preferable, and S-shaped contrast transform in which an inflection point is at low lightness 20≦L*≦70 and the low lightness side is concave and the high lightness side is convex causes tone jump to hardly occur. Further, when image data are for a portrait (personal photographing), it is preferable to carry out chroma adjustment for a range of flesh color by conducting chromatic color.

As a method of measuring contrast of a camera, it is possible to measure by photographing a gray chart at neutral, for example, and by photographing Munsell chart with, chromatic colors, and its level can be calculated based on correlation between image data before image processing and image data after image processing.

(Structure 8)

The image processing apparatus according to the Structure 6 or Structure 7, wherein the image processing section emphasizes chroma more as lightness of the image data becomes lower.

When the chroma is more emphasized as lightness becomes lower, the chroma on the visible image is changed for the pixel belonging to the specific color area. As a specific color area, chroma adjustment after image processing is conducted for that before image processing for each lightness area that is distinguished by a color value on the visible image and defined by lightness, whereby, changes in chroma under the environmental light is suppressed and three-dimensional feeling is improved. Further, by making an inclination of reproduction of chroma of L* 70 or more to be 0.6-1.0, connections of flesh color areas become smooth, and tone jump hardly occurs, which is preferable. Further, by making an inclination of reproduction of chroma of L* 50 or less to be 1 or more, chroma decline hardly occurs on the circumference shadow of a face, which is preferable as a portrait photograph. In particular, by making an inclination of chroma reproduction to be greater as lightness goes down to L* 90, 80, 70 and to 60-30, chroma decline on the circumference shadow of a face can be suppressed smoothly, and three-dimensional feeling is improved, which is preferable.

(Structure 9)

The image processing apparatus according to any one of the Structure 6 to Structure 8, wherein the image processing section emphasizes a level of a chroma emphasis for the image data as chroma becomes greater.

When a level of chroma emphasis is emphasized as the chroma grows greater, toner jump does not occur on the image description of the background, and the image is improved to be a preferable image having three-dimensional feeling of a face as a portrait. Further, on a portion of C* 15or less, an inclination becomes 0.6-1.4, and on a portion of C* 15 or more, inclinations L* 50, 60, 70 and 80 become smaller gradually, chroma reproduction lines do not intersect, therefore, tone jump does not occur on an achromatic color often used for the background, which is preferable for suppressing image deterioration.

(Structure 10)

The image processing apparatus according to any one of the Structure 6 to Structure 9, wherein the image processing section increases a level of a chroma emphasis for the image data depending on an amount of changes in lightness.

When a level of a chroma emphasis is emphasized depending on an amount of changes in lightness, tone jump hardly occurs, chroma decline can be suppressed, and image quality as a portrait photograph can be improved. In particular, by emphasizing chroma reproduction in first-order proportion to an amount of changes of L*, chroma decline on the circumference shadow of a face can be suppressed smoothly, and three-dimensional feeling becomes excellent, which is preferable. As a measuring method, it is possible to measure by photographing a gray chart at neutral, for example, and by photographing Munsell chart with chromatic colors. In addition, it is possible to prepare image data to conduct image processing, and to measure the image data to use a color value therefrom for the measurement.

(Structure 11)

The image processing apparatus according to any one of the Structure 6 to Structure 10, wherein the image processing section lowers maximum lightness of the image data after image processing to be lower than that of maximum lightness of the image data before image processing.

When maximum lightness of the image data after image processing is lowered to be lower than that of maximum lightness of the image data before image processing, it is easy to obtain an improvement of three-dimensional feeling on the highlight, which is preferable. What is especially preferable is to lower by 3 or more in maximum lightness L*, and to combine any one of the Structure 6 to Structure 10, to obtain natural finish, which is preferable.

(Structure 12)

The image processing apparatus according to any one of the Structure 6 to Structure 11, wherein the image processing section compresses a hue reproduction angle in a range of a flesh color area corresponding to a flesh color of the image data.

When the hue reproduction angle in a range of the flesh color area is compressed, hue fluctuation of a flesh color hardly occurs, chroma decline on the circumference shadow can be suppressed, three-dimensional feeling can be improved and image quality can be improved to be excellent in particular, which is preferable.

According to the foregoing, for preventing partial image quality decline caused by compression change of hue in a prescribed amount on the visible image, by determining, for example, transform characteristics so that chroma changes may be processed properly on each visible image for a pixel belonging to any one of plural color areas, it becomes possible to make the finish of a portion corresponding to a prescribed color area on the visible image to be more preferable. Wherein, the transform characteristics is determined by suppressing hue and contrast changes on a portion corresponding to any one of plural color areas on the visible image as described in Structure 6, or the transform characteristics is determined such that suppression level of chroma changes on a visible image for a pixel positioned in a prescribed color area is determined in accordance with a prescribed lightness area as described in Structure 8.

(Structure 13)

The image processing apparatus according to any one of the Structure 1 to Structure 12, wherein image data to be subjected to image processing are scene-referred data in the course of photographing and/or RAW data.

Since the image data to be subjected to image processing are scene-referred data in the course of photographing and/or RAW data, noise in image processing hardly occurs, and various effects of the invention are obtained, which is preferable. Though a process for processing is not limited in particular, it is preferable that processing is conducted on image data after AD transform of a digital camera or on RAW image data in the case of AD transform after photographing, and it is preferable to conduct image processing of the invention after confirming visually in application in the course of photographing for images, which is free from a failure. Image data mentioned here mean CCD image data of a digital camera, and they may include also RAW image data of RGGB, image data wherein other processing such as sharpness, moire or gradation compression is applied to the RAW image data of RGB and image data immediately before the known data development for transforming actually to a visible image by tiff/bmp/jpeg/mpeg.

Further, by conducting image processing by holding a profile of an image inputting section such as DSC of image data, and by preparing a transform expression based on the aforesaid input profile, it is possible to carry out color management while making the most of color area information on each image, which is preferable. What is further preferable is to conduct image transform by holding a profile at color temperature D50, as PCS (Profile Connection Space), which is capable of outputting prints stably, and is preferable as a system. As a profile, Color Space Conversion ICC profile can be used for input image such as a digital image. What is especially preferable is to conduct image processing by combining image transform with input by the use of a device-link profile as an output target, which is preferable from the viewpoint of suppressing image deterioration in the course of transform.

(Structure 14)

An image processing apparatus equipped with an image processing section that conducts image processing for image data, wherein maximum lightness of image data for a reflection-type print formed through subtractive color mixture is lowered, compared with visible image data for a transmission-type film formed through additive color mixture and/or for the monitor.

In the case of processing recorded image data, it is possible to realize appropriate color reproduction in association of visible image data for a transmission-type film formed through additive color mixture and/or the monitor with image data for a reflection-type print formed through subtractive color mixture, by lowering maximum lightness of image data for a reflection-type print formed through subtractive color mixture, compared with visible image data for a transmission-type film formed through additive color mixture and/or the monitor.

It is further preferable that image data have less photographic fog and a preferable print of a reflection-type image can be obtained, when γ of a highlight of image data used for a reflection-type print is as low in contrast as +3% or more or maximum lightness is as low as 3-10 in L*. It is possible to realize preferable color reproduction in Japan and other Asian countries, by making it possible that color balance on a highlight or on a point of maximum lightness shows more +magenta in reflection-type image data.

(Structure 15)

The image processing apparatus according to any one of the Structure 1 to Structure 14, wherein the image processing section transforms image data subjected-to image processing into output color image signals based on characteristics of the image outputting section.

Under the condition that image data subjected to image processing are transformed into output color image signals based on characteristics of an image output section, preferable reflection-type outputted materials can be obtained by conducting image transform for each different output for those including a silver halide medium, an inkjet medium and a sublimation-type medium, which is preferable.

(Structure 16)

The image processing apparatus according to any one of the Structure 1 to Structure 15, wherein the image processing section is equipped with the first transform section that transforms input color image signals of the image data into signals in a standard color space based on characteristics of the image inputting section, the second transform section that transforms signals in the standard color space based on characteristics of the image outputting section, and with the third transform section that transforms signals in the standard color space transformed by the second transform section into output color image signals.

By transforming input color image signals of image data into signals in the standard color space based on characteristics of the image inputting section, and by transforming signals in the standard color space into output color image signals based on characteristics of the image outputting section, color area information in each image can further be used practically in each medium for color management, and color area information of each image can be obtained for each different output for those including a silver halide medium, an inkjet medium and a sublimation-type medium, which is preferable. More preferably, as a standard color space, image transforming while holding a profile at color temperature D50 is preferable because a difference from the observation is small. Further, the use of a function called LUT (Look Up Table) for transforming is preferable because its versatility is high and stable. Further, for transforming of input and output target, it is preferable to transform by combining the aforesaid two transforms (preparing the third transform expression), from the viewpoint of a noise of transform and easy operations.

Since the transform of signals in a standard color space into output color image signals based on characteristics of the image output section is the transform based on gamut mapping, color area information in each image is put to practical use in each medium for color management to make color saturation to hardly occur, and thereby, stable and high image quality prints can be obtained even for different output in a silver halide medium, an inkjet medium and a sublimation-type medium, which is preferable.

It is especially preferable to conduct gamut mapping for color image signals after image processing so that lightness at high chroma may be lowered and a broad output color reproduction area may be given, because massive feeling that is the same as that in a conventional analogue photograph can be obtained. When each output reproduction area is narrow, it is preferable to compress chroma as it goes up to prevent saturation, because tone jump is controlled.

(Structure 17)

The image processing apparatus according to any one of the Structure 1 to Structure 16, wherein the image processing section conducts image processing that causes no saturation of chroma changes by the use of a color gamut that is broader than a color gamut of the image data before image processing, based on a color reproduction range in an output system of the image data.

By conducting image processing that causes no saturation of chroma changes by the use of a color gamut that is broader than a color gamut of the image data before image processing, based on a color reproduction range in an output system of the image data, color saturation and tone jump both caused by transforming in a narrow color gamut of the image data can be controlled, when conducting compression, chroma transform and emphasis, which is preferable.

(Structure 18)

The image processing apparatus according to any one of the Structure 1 to Structure 17, wherein the image processing section conducts image processing on image data that holds profile of an image inputting section.

By conducting image processing on image data that holds profile of an image inputting section of the image data, stable color management can be carried out, and images and prints having high quality can be obtained.

(Structure 19)

The image processing apparatus according to any one of the Structure 1 to Structure 18, wherein the image processing section conducts image processing on image data for outputting on a silver halide medium.

In this image processing apparatus, a print which has a glossy feel similar to that of analogue photographs and is excellent in color reproduction can be obtained, because its image processing is under the assumption of silver halide. medium output, which is preferable.

As a medium for output, silver halide color paper and positive silver halide film are preferable, although there is no limitation, in particular, and when transforming, it is preferable to conduct gamut mapping with RGB→Lab transformation, which offers an excellent glossy feel and substantial feeling similar to that of analogue photograph, while controlling color saturation, because there are some cases where a color gamut of silver halide is narrow.

(Structure 20)

The image processing apparatus according to any one of the Structure 1 to Structure 19, wherein the image processing section compresses a hue reproduction angle more greatly in a flesh color area of human image data, compared with image data of still-life.

By compressing more greatly a hue reproduction angle in a flesh color area of image data for a person (portrait) compared with image data of still-life (still-life shot), it is possible to produce preferable images having excellent three-dimensional feeling stably without damaging description of the surface of an object, even in the scene other than a portrait, which is preferable.

(Structure 21)

The image processing apparatus according to any one of the Structure 1 to Structure 20, wherein the image processing section conducts scene discrimination and/or face image extraction, and changes transformation conditions for image processing based on the results of the scene discrimination or the face image extraction.

By conducting scene discrimination and/or face image extraction of image data and by changing transformation conditions for image processing based on the results of the scene discrimination or the face image extraction, it is possible to restrain stably environmental fluctuations for photographing and to obtain excellent color reproduction. Though there is no limitation in particular, a selection can be made by scene discrimination, and it is possible to select and use without damaging an effect of the invention accordingly, by judging portrait or still-life under a certain condition, following algorithm at each factor in a size of a flesh color area and/or face recognition. It is especially preferable to conduct by changing image processing by controlling a hue target angle by detecting color temperatures, further by conducting weighting with the aforesaid factors and by considering, an amount of compression of hue, a target angle, a method of compression, a contrast difference between a chromatic color and neutral, a contrast form, further an amount of chroma emphasis, a method, a gamut mapping method in image processing and an amount, of the invention.

(Structure 22)

An image photographing apparatus having therein a photographing section creating image data by photographing a photographic object and an image processing apparatus according to any one of the Structure 1 to Structure 21 wherein the image processing section conducts image processing for image data created by the photographing section.

(Structure 23)

An image processing system having therein an image input section that inputs image data, an image output section that outputs image data and an image processing apparatus according to any one of the structure 1 to Structure 21, wherein the image processing section conducts image processing for image data inputted from the image input section, and outputs them to the aforesaid image output section.

(Structure 24)

An image processing method for conducting image processing for image data, wherein there is included an image processing process to compress a hue reproduction angle in a range of a flesh color area corresponding to a flesh color in image data.

(Structure 25)

The image processing method according to the Structure 24, wherein a range of the flesh color area is converged to a target hue reproduction angle of the specified target, and thereby, the hue reproduction angle is compressed.

(Structure 26)

The image processing method according to the Structure 24 or Structure 25, wherein in the image processing process, a center of the compression of the hue reproduction angle in the flesh color area and/or an amount of compression is changed based on color temperature and white point of illumination light at image data generation.

(Structure 27)

The image processing method according to any one of the Structure 24 to Structure 26, wherein a level of the compression of the hue reproduction angle is enhanced as the angle recedes from the target hue reproduction angle, in the case of converging a range of the flesh color area to a target hue reproduction angle determined specifically, in the aforesaid image processing process.

(Structure 28)

The image processing method according to any one of the Structure 24 to Structure 27, wherein a level of the compression of the hue reproduction angle is lowered as chroma increases, in the aforesaid image processing process.

(Structure 29)

An image processing method for conducting image processing for image data, wherein there is included an image processing process wherein contrast in neutral of image data is made to be in low contrast, and contrast of other chromatic colors is made to be in high contrast.

(Structure 30)

The image processing method according to the Structure 29, wherein a difference between contrast of chromatic colors of the image data and contrast in neutral is made to be 5% or more.

(Structure 31)

The image processing method according to the Structure 29 or the Structure 30, wherein chroma is emphasized more as lightness of the image data declines to be lower.

(Structure 32)

The image processing method according to the Structure 29 to the Structure 31, wherein a level of emphasis of chroma of the image data is emphasized more as the chroma grows greater.

(Structure 33)

The image processing method according to any one of the Structure 29 to the Structure 32, wherein a level of emphasis of chroma of the image data is emphasized more based on an amount of changes in lightness, in the image processing process.

(Structure 34).

The image processing method according to any one of the Structure 29 to the Structure 33, wherein lightness of the maximum lightness of the image data after image processing is lowered to be lower than that before image processing, in the image processing process.

(Structure 35)

The image processing method according to any one of the Structure 29 to the Structure 34, wherein a hue reproduction angle in a range of-the flesh color area corresponding to the flesh color of the image data is compressed, in the image processing process.

(Structure 36)

The image processing method according to any one of the Structure 24 to the Structure 35, wherein image data to be subjected image processing are scene-referred data in the course of photographing and/or RAW data.

(Structure 37)

An image processing method for conducting image processing for image data, wherein there is included an image processing process wherein maximum lightness of image data for a reflection-type print formed through subtractive color mixture is lowered, compared with visible image data for a transmission-type film formed through additive color mixture and/or for the monitor.

(Structure 38)

The image processing method according to any one of the Structure 24 to the Structure 37, wherein image data which have been subjected to image processing are transformed to output color image signals, based on characteristic features of the image output section, in the image processing process.

(Structure 39)

The image processing method according to any one of the Structure 24 to the Structure 38, wherein the image processing process includes the third transform process of the standard color space including the first transform process that transforms input color image signals of the image data into signals in a standard color space based on characteristics of the image inputting section, and the second transform process that transforms signals in the standard color space into output color image signals based on characteristics of the image outputting section in the standard color space.

(Structure 40)

The image processing method according to any one of the Structure 24 to the Structure 39, wherein, in the image processing process, image processing causing no saturation of chroma changes is conducted by using a color gamut that is broader than that of the image data before image processing, based on the color reproduction range in the output style of the image data.

(Structure 41)

The image processing method according to any one of the Structure 24 to the Structure 40, wherein, image data holding a profile of an image input section are subjected to image processing, in the image processing process.

(Structure 42)

The image processing method according to any one of the Structure 24 to the Structure 41, wherein, image processing is conducted on image data for output on a silver halide medium, in the image processing process.

(Structure 43)

The image processing method according to any one of the Structure 24 to the Structure 42, wherein a hue reproduction angle is compressed more greatly in a flesh color area of human image data, compared with image data of still-life, in the image processing process.

(Structure 44)

The image processing method according to any one of the Structure 24 to the Structure 43, wherein scene discrimination of the image data and/or face image extraction is carried out, and a change of transformation conditions for image processing is made based on the results of the scene discrimination or the face image extraction, in the image processing process.

(Structure 45)

A program for enabling a computer to realize an image processing function to compress a hue reproduction angle in a range of a flesh color area corresponding to the flesh color of the image data.

(Structure 46)

The program according to the Structure 45, wherein a range of the flesh color area is converged to a specified target hue reproduction angle in the image processing function, and thereby, the hue reproduction angle is compressed.

(Structure 47)

The program according to the Structure 45 or the Structure 46, wherein the image processing function changes a center of a compressed hue reproduction angle in a range of the flesh color area and/or an amount of compression, based on color temperature and white point of illumination light at image data generation.

(Structure 48)

The program according to any one of the Structure 45 to the Structure 47, wherein a level of the compression of the hue reproduction angle is enhanced as the angle recedes from the target hue reproduction angle, in the case of converging a range of the flesh color area to a target hue reproduction angle determined specifically, in the aforesaid image processing function.

(Structure 49)

The program according to any one of the Structure 45 to the Structure 48, wherein the image processing function lowers a level of the compression of the hue reproduction angle as the angle recedes from the target hue reproduction angle, in the case of converging a range of the flesh color area to a target hue reproduction angle determined specifically.

(Structure 50)

A program for realizing, on a computer, an image processing function to make contrast in neutral of image data to be in low contrast, and to make contrast of other chromatic colors to be in high contrast.

(Structure 51)

The program according to the Structure 50, wherein the image processing function makes a difference between contrast of chromatic colors of the image data and contrast in neutral to be 5% or more.

(Structure 52)

The program according to the Structure 50 or the Structure 51, wherein the image processing function makes a difference between contrast of chromatic colors of the image data and contrast in neutral to be 5% or more.

(Structure 53)

The program according to any one of the Structure 50 to the Structure 52, wherein the image processing function emphasizes a level of chroma emphasis of the image data as the chroma grows greater.

(Structure 54)

The program according to any one of the Structure 50 to the Structure 53, wherein the image processing function emphasizes more a level of emphasis of chroma of the image data, based on an amount of changes in lightness.

(Structure 55)

The program according to any one of the Structure 50 to the Structure 54, wherein the image processing function lowers lightness of maximum lightness of the image data after image processing to be lower than that of maximum lightness of the image data before image processing.

(Structure 56)

The program according to any one of the Structure 50 to the Structure 55, wherein the image processing function compresses the hue reproduction angle in a range of the flesh color area corresponding to the flesh color of the image data.

(Structure 57)

The program according to any one of the Structure 50 to the Structure 56,-wherein image data to be subjected to image processing are scene-referred data in the course of photographing and/or RAW data.

(Structure 58)

A program for enabling, a computer to realize an image processing function to lower the maximum lightness of the image data for a reflection-type print formed through subtractive color mixture, compared with visible image data for transmission-type film formed through additive color mixture and/or for the monitor.

(Structure 59)

The program according to any one of the Structure 45 to the Structure 58, wherein the image processing function transforms image data subjected to image processing into output color image signals based on characteristics of an image output section.

(Structure 60)

The program according to any one of the Structure 45 to the Structure 59, wherein the image processing function includes the third transform function of the standard color space including the first transform process that transforms input color image signals of the image data into signals in a standard color space based on characteristics of the image inputting section, and the second transform process that transforms signals in the standard color space into output color image signals based on characteristics of the image outputting section in the standard color space.

(Structure 61)

The program according to any one-of the Structure 45 to the Structure 60, wherein the image processing function conducts image processing causing no saturation of chroma changes by using a color gamut that is broader than that of the image data before image processing, based on the color reproduction range in the output style of the image data.

(Structure 62)

The program according to any one of the Structure 45 to the Structure 61, wherein the image processing function conducts image processing on image data holding a profile of an image input section.

(Structure 63)

The program according to any one of the Structure 45 to the Structure 62, wherein the image processing function conducts image processing on image data for output on a silver halide medium.

(Structure 64)

The program according to any one of the Structure 45 to the Structure 63, wherein the image processing function compresses more greatly a hue reproduction angle in a flesh color area of human image data, compared with image data of still-life.

(Structure 65)

The program according to any one of the Structure 45 to the Structure 64, wherein the image processing function conducts scene discrimination of the image data and/or face image extraction, and changes transformation conditions for image processing, based on the results of the scene discrimination or the face image extraction.

The first, second and third embodiments of the invention will be explained in detail in sequence as follows, referring to the drawings.

### First Embodiment

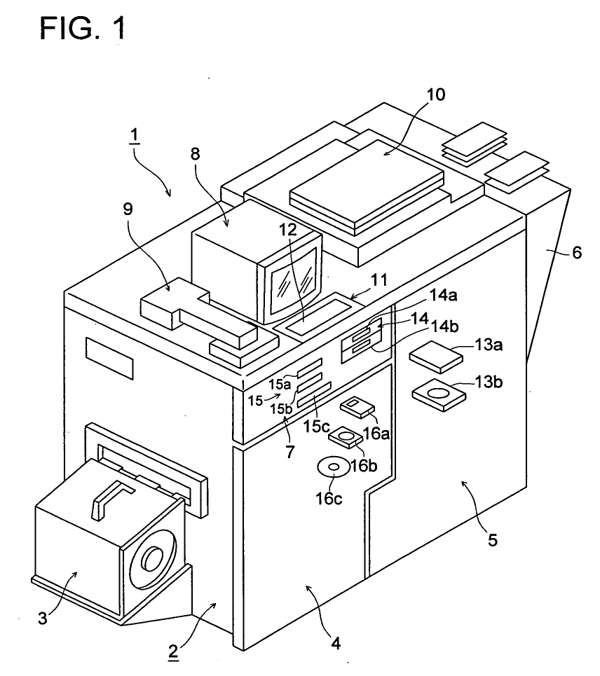

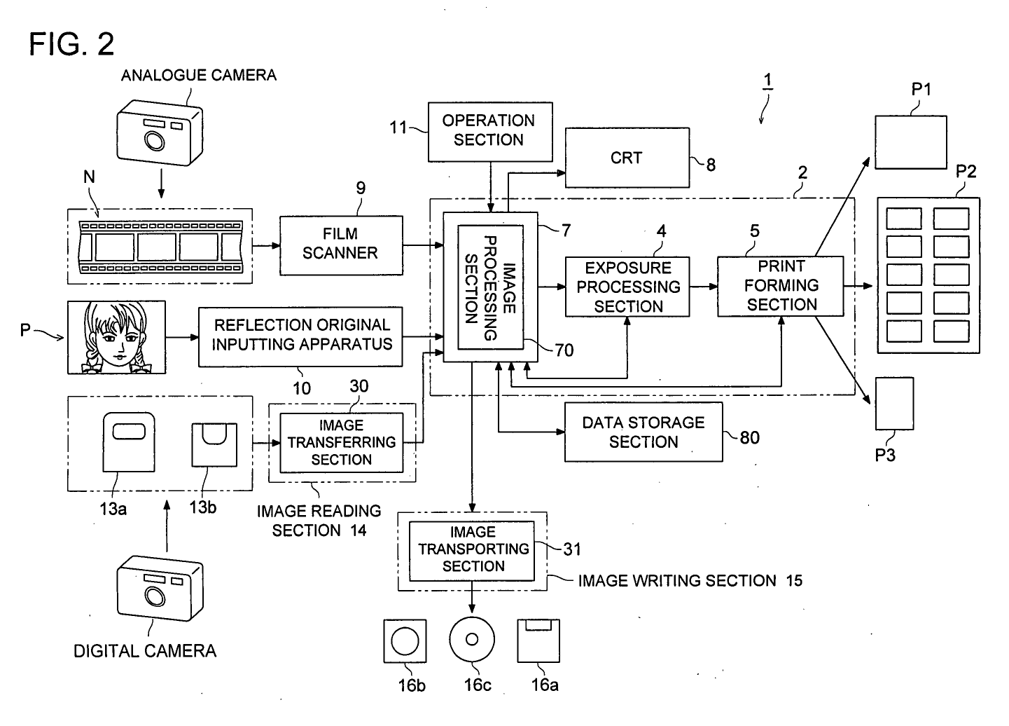

The first embodiment of the invention will be explained with reference to the accompanying drawings FIG. 1-FIG. 13. First, an apparatus structure of image recording apparatus 1 representing an image processing system of the present embodiment will be explained, referring to FIG. 1 and FIG. 2. FIG. 1 shows an external appearance of the image recording apparatus 1, and FIG. 2 shows a schematic structure of the image recording apparatus 1.

Though the image recording apparatus 1 illustrated is one wherein photosensitive materials are exposed to light and are developed, for making prints, the invention is not limited to this, and those which make prints based on image information such as, for example, print making apparatuses of an inkjet type, an electrophotographic type, a thermal recording type and a sublimation type can also be used.

The image recording apparatus 1 is equipped with magazine loading section 3 which is arranged on the left side of main body 2 of an image processing apparatus, and with exposure processing section 4 that gives exposure to photosensitive material representing a recording medium as well as print forming section 5 that develops and dries exposed photosensitive material to make print, both are arranged in the main body 2, and a finished print is ejected to tray 6 provided on the right side of the main body 2. Further, inside the main body 2, control section 7 is provided at the upper position of exposure processing section 4.

Further, CRT 8 is arranged on the upper portion of the main body 2. This CRT 8 constitutes a display section that displays, on its screen, an image of image information for a print to be made. Film scanner 9 representing a transmission-type original reading device is arranged on the left side of CRT 8 , and reflection original inputting apparatus 10 is arranged on the right side of CRT 8.

There are photographic photosensitive materials as an original for be read by the film scanner 9 or by the reflection original inputting apparatus 10, and as a photographic photosensitive material, there are given a color negative film and a color reversal film on which frame image information obtained by an analogue camera through imaging is recorded. A film scanner in the film scanner 9 can transform to digital information to obtain frame image information. When a photographic photosensitive material is a color paper, frame image information can be obtained by a flat bed scanner of the reflection original inputting apparatus 10.

There is further provided image reading section 14 at the position of the control section 7 on the main body 2. On the image reading section 14, there are arranged adapter 14 a for PC card and adapter 14b for a floppy (a registered trademark) disc, so that PC card 13a and floppy® (a registered trademark) disc 13b can be inserted respectively. PC card 13a has a memory on which plural pieces of frame image information obtained by a digital camera through imaging are recorded. On floppy® (a registered trademark) disc 13b, there are recorded plural pieces of frame image information obtained by, for example, a digital camera.

On the front side of CRT 8, there is arranged operation section 11 on which information input section 12 is provided, and the information input section 12 is constructed by, for example, a touch panel. A recording medium having frame image information may also be a multi-media card, a memory stick, MD data, CD-ROM or DVD-ROM.

Incidentally, though operation section 11, CRT 8, film scanner 9, reflection original inputting apparatus 10 and image reading section 14 are provided solidly on the main body 2 to constitute the apparatus, any one or more of them may be provided separately.

There is further provided image writing section 15 at the position-of the control section 7 on the main body 2. On the image writing section 15, there are provided adapter 15a for FD, adapter 15b for MO and adapter 15c for an optical disc, so that FD 16a, MO 16b and optical disc 16c may be inserted, thereby, image information can be written on an image recording medium.

On the control section 7, there is further provided an unillustrated communication section which directly receives image signals that express pickup images and print order from other computers in the same facility or from a remote computer through Internet, and can function as the so-called network printer device.

The control section 7 of the image recording apparatus 1 reads information of the original coming from the film scanner 9 or from the reflection original inputting apparatus 10 based on directives information coming from information input section 12, to obtain image information, and displays it on CRT 8.

The image recording apparatus 1 has therein data accumulation section 80. Image information, order information corresponding to the image information (information about how many prints from which frame of image, and information about a print size) and information such as image processing conditions for printing, are sequentially recorded and accumulated in data accumulation section 80. From film scanner 9, frame image data from developed negative film N obtained by developing a negative film obtained by an analogue camera through imaging are inputted, while, from the reflection original inputting apparatus 10, frame image data from print P wherein frame images are printed on a photographic paper and developed are inputted.

The control section 7 has image processing section 70 which conducts image processing of the invention on the image signal to form image information for exposure, and sends it to exposure processing section 4.

In the exposure processing section 4, exposure of an image is given to a photosensitive material, and this photosensitive material is sent to print forming section 5 where the exposed photosensitive material is developed and dried, thus, prints P1, P2 and P3 are prepared. The print P1 includes prints respectively in a service size, a High Definition Television size and a panorama size, the print P2 includes a print in A4 size and print P3 includes a print in a business card size.

The image recording apparatus 1 is equipped with image reading section 14 that reads and transfers frame image information on PC card 13a and floppy (a registered trademark) disc 13b which are obtained by a digital camera through imaging and stored. On this image reading section 14, there are provided an adapter for PC card and an adapter for a floppy (a registered trademark) disc, as image transfer section 30. PC card 13a is inserted in the adapter 14 for PC card, or a floppy (a registered trademark) disc 13b is inserted in the adapter 14b for a floppy (a registered trademark) disc, and frame image information recorded on PC card 13a or floppy (a registered trademark) disc 13b is transferred to control section 7 that is composed of reading microcomputers. As adapter 14a for PC card, PC card reader and PC card slot, for example, are used.

On the image writing section 15, adapter 15a for FD, adapter 15b for MO and adapter 15c for an optical disc are provided as image transporting section 31, so that FD 16a, MO16b and optical disc 16c may be inserted, thus, image information can be written in image recording media.

By using an unillustrated communication section connected to image processing section 70, image signals indicating photographed images after subjected to image processing of the invention and order information incidental to the image signals can be sent to another computer in the same facility and to a remote computer through Internet.

The image recording apparatus 1 has therein an image input section that takes in images of various digital media and image information obtained by split photometry of image originals, an image processing section that conducts image processing of the invention on image data of input images taken in from the image input section, an image output section that displays processed images, or outputs them as prints, or writes them on image recording media, and an order communication section that transmits image signals and order information incidental to the image signals to another computer in the same facility through communication line or to a remote computer through Internet. The image input section is composed of image reading section 14 that takes in image information of images of various types digital media, film scanner 9 that takes in image information obtained through divided photometry for image originals, reflection original inputting apparatus 10 and an unillustrated communication section. The image processing section is provided on image processing section 70, and the image output section is composed of CRT 8 that displays images, exposure processing section 4, print forming section 5, image writing section 15 that writes on image recording media and of an unillustrated communication section.

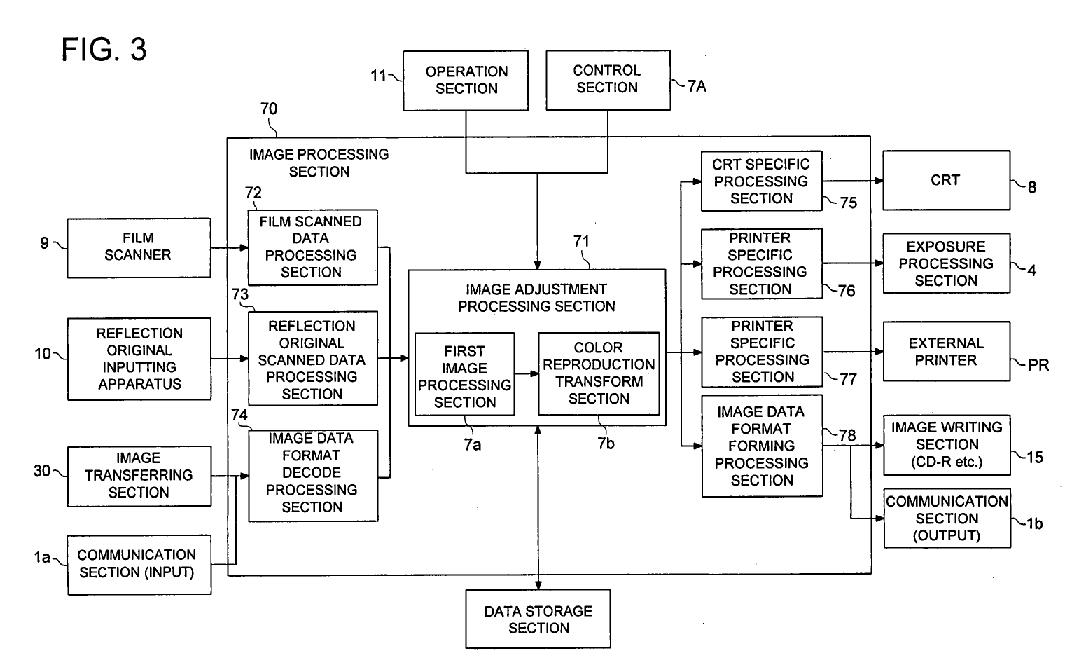

FIG. 3 shows a schematic structure of the image processing section 70. Image adjustment processing section in the image processing section 70 is composed of color reproduction transform section 7b and first image processing section 7a, as shown in FIG. 3. Image signals inputted from film scanner 9 are subjected to correction operation, negative/positive inversion in the case of a negative original, gray balance adjustment and contrast adjustment which are inherent in film scanner 9, in film scanned data processing section 72, and are sent to image adjustment processing section 71. Further, a film size, negative and positive types, ISO speed recorded on a film optically or magnetically, a name of a maker, information about primary photographic object and information about photographing conditions (for example, contents of description information of APS) are sent together to the image adjustment processing section 71.

Image signals inputted from reflection original inputting apparatus 10 are subjected to proofreading operations, negative/positive inversion in the case of a negative original, gray balance adjustment and contrast adjustment which are inherent in the reflection original inputting apparatus 10, in reflection original scanned data processing section. 73, to be sent to image adjustment processing section 71.

Image signals inputted from image transferring section 30 or from communication section 1a are subjected to restoration of compression code and to transform of a mode of expression of color signals in case of need, following the data format of that image signals, in image data format decode processing section 74, and the image signals are transformed to the data format suitable for calculation in the image processing section 70 to be sent to image adjustment processing section 71. Further, header information of image signals, information about a name of a maker of DSC (digital camera) acquired from tag information, a name of a model and a primary photographic object and information about photographing conditions are sent together to the image adjustment processing section 71.

In addition to the foregoing, information about primary photographic objects coming from film scanner 9, reflection original inputting apparatus 10, image transferring section 30 and communication section 1a and information about photographing conditions can also be sent to image adjustment processing section 71 from operation section 11, in a form to complement and to replenish them. Though a size of an image to be outputted is inputted from operation section 11, if there are specifications for a size of the output image sent to communication section 1a and for a size of the output image embedded in header information of image signals acquired by image transferring section 30 or in tag information, in addition to the foregoing, image data format decode processing section 74 detects that information to transfer to image adjustment processing section 71.

In the meantime, as the image processing conducted in first image processing section 7a, there are given image processing operations for improving image quality of an image to be outputted such as, for example, gray balance adjustment for an image, density adjustment, gradation control, hyper-tone processing to compress gradation of low frequency luminance component of an image, and hyper-sharpness processing to emphasize sharpness while controlling graininess, which are carried out for image data received from film scanner 9, reflection original inputting apparatus 10, image transferring section 30, and communication section 1a, based on directives of operation section 11 or of control section 7A. Further, image processing such as those to change the image intentionally (for example, image processing to finish an image of a person to be slender, or to remove wrinkles) may also be practiced, and after that, adjustment of hue, contrast between a chromatic color and neutral, chroma and of the maximum lightness, is conducted, through a color reproduction transform section serving as image processing relating to the invention, and processed image signals are sent to SRT specific processing section 75, printer specific processing sections 76 and 77, image data format forming processing section 78, and data storage section 80. In the invention, color reproduction transform of the invention may be carried out before image processing of the first image processing section 7a within a range where an effect of the invention is not disturbed, and processing of noise and frequency is not problematic.

In CRT specific processing section 75, there are conducted processing operations such as a change of the number of pixels and color matching in case of need, for the image data received from image adjustment processing section 71, and signals for display combined with information requiring display such as control information are sent to CRT. 8.

In printer specific processing section 76, printer-specific proofreading processing, color matching and a change of the number of pixels in case of need, are conducted, and image signals are sent to exposure processing section 4. When external printer PR such as a large-sized inkjet printer is further connected to image recording apparatus 1, printer specific processing section 77 is provided for each external printer PR to be connected, so that appropriate printer-specific correction processing, color matching and a change of the number of pixels may be carried out (details will be described later). In image data format forming processing section 78, transforms to various types of general-purpose image formats represented by JPEG, TIFF and Exif are conducted if necessary, and image signals are transferred to image writing section 15 and communication section lb.

The aforesaid division including film scanned data processing section 72, reflection original scanned data processing section 73, image data format decode processing section 74, image adjustment processing section 71, CRT specific processing section 75, printer specific processing sections 76 and 77 and image data format forming processing section 78 is a division provided for easy understanding of the function of image processing section 70, and it does not necessarily need to be realized as a device which is physically independent, and it may also be realized as a division of types of software processing in, for example, a single CPU.

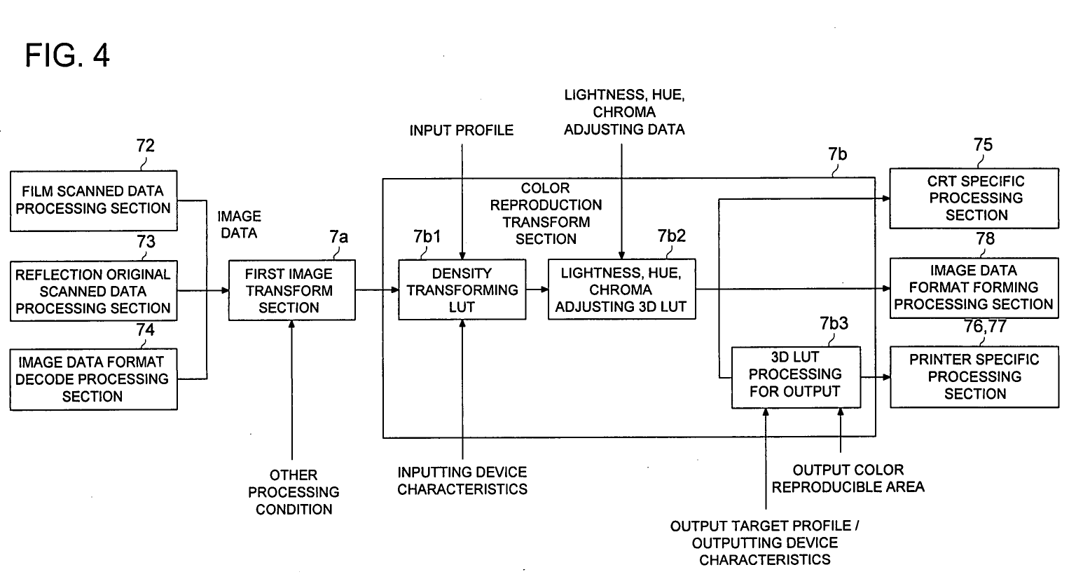

FIG. 4 shows a schematic structure of color reproduction transform section 7b. As shown in FIG. 4, the color reproduction transform section 7b is constituted in a way that look-up table (LUT) 7b1 for transform density for transforming density of image data inputted so that density of an image expressed by inputted image data may be reproduced properly on the outputted image (an image visualized on a photographic paper through an outputting form to record an image on a photographic paper and an image displayed on CRT by using image data recorded through an outputting form to record image data on CD-R, which correspond to visual images relating to the invention) and three-dimensional look-up table (3D-LUT) 7b2 for conducting adjustment of hue of outputted images, contrast, the maximum lightness and chroma, when adjustment of hue, contrast between a chromatic color and neutral, chroma and the maximum lightness is indicated are connected in sequence, while, image writing sections such as CRT, a printer and CD-R are connected to an output end of the image data.

Further, 3D-LUT (which will be described in detail later) 7b3 corresponds to an image processing section in the case of conducting gamut mapping by receiving output device characteristic data.

To image processing section 70, there are further connected operation section 11 and control section 7A where an operator who has tested displayed output image formed by a key board connected to an input-output port of the aforesaid microcomputer and a mouse, for example, operates key correction and inputs the results of the test. When processing conditions are decided after the test, the decided processing conditions are notified to the image processing section 70.

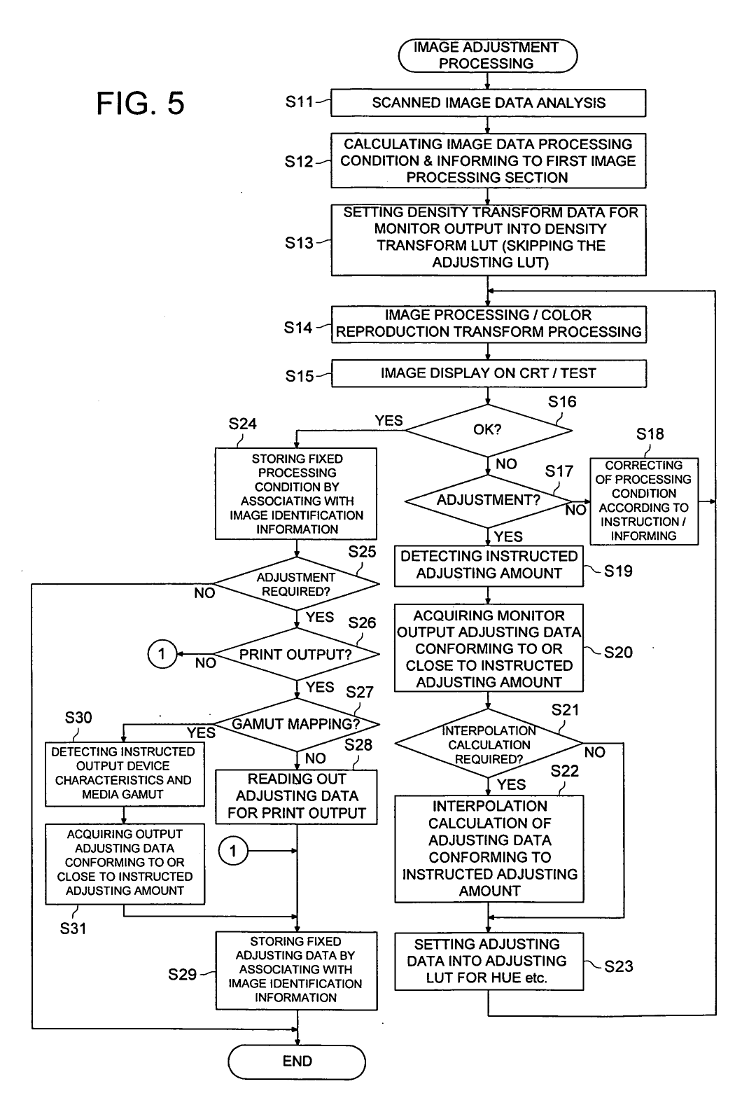

Next, operations in the present embodiment will be explained as follows, referring to FIG. 5 showing image adjustment processing conducted by the image processing section 70 of the image recording apparatus 1. FIG. 5 shows image adjustment processing. Incidentally, this image adjustment processing is conducted by the image processing section 70, each time a single unit of image data is read in film scanner 9.

First, low resolution image data scanned and then stored in data storage section 80 are taken in, and analyses of image data including extraction of a primary portion in the image (for example, an area corresponding to a face of a person (face area)) and processing such as calculation of an amount of various types of image characteristics, are carried out (step S11). Further, optimum processing conditions for image processing to be conducted for image data taken in at high resolution are calculated, based on the results of the analyses of the image data in step S11, and calculated processing conditions are notified to the first image processing section 7a (step S12 ). In the meantime, the operation section 11 and the control section 7A correspond to input section of an indication and specification for increasing compression of a hue reproduction angle in a flesh color area of image data for a person to be greater than that for still-life image data, and an indication and specification for conducting scene discrimination and/or face image extraction for image data and for changing transform conditions for image processing based on the results of the scene discrimination and/or face image extraction.

In the present embodiment, there are available three types of outputting forms including display of an image on CRT 8 (monitor display), recording (print output) of an image on a photographic paper by a printer (exposure processing section 4, print forming section 5 and external printer PR), and recording in an image writing section.(writing on CD-R), as an outputting form, and the image data can be displayed on CRT 8 with preferable image quality without conducting a specific post-processing, when displaying on a CRT monitor, because image data written on CD-R are generally used for display on CRT monitor.

In the present embodiment, density transform data for display on a monitor and density transform data for writing on CD-R can be made common, and two types of density transform including one for print output and one for monitor display and CD-R writing can be accumulated to be stored. Though the invention is preferably used especially for print output, it can also be used for monitor display and CD-R writing, if it is required by an instruction.

For low resolution image data stored in data storage section 80, the first image processing section 7a conducts various types of image processing operations, and color reproduction transform section 7b conducts color reproduction transform processing (only density transform processing by LUT7b1 for density transform, in this case) (step S13 ).

owing to this, the first image processing section 7a takes in low resolution image data from scanner 9, and generates image data estimated after conducting image processing equivalent to image processing conducted by the first image processing section 7a for high resolution image data based on the processing conditions notified by processing in the step S12 (step S14 ). Image data generated by the first image processing section 7a are transformed in terms of density by LUT7b1 for density transform of color reproduction transform section 7b so that an image displayed on CRT 8 is expressed (to be in the state of color management) properly corresponding with an image on photographic paper or a film such as a reflection-type medium or a transmission-type medium obtained through exposure processing and outputting.

When image data subjected to color reproduction processing by color reproduction transform section 7b are outputted on CRT 8, an image expressed by the aforesaid image data is displayed on CRT 8 as an outputted image (step S15). In step S15, it is possible to cause an operator to approve finishes of various portions on the outputted image by indicating, on CRT 8, a message requiring an approval for an image outputted on CRT 8.

Meanwhile, when requiring a test for an outputted image by displaying the output image on CRT 8, an operator confirms the outputted image-displayed on CRT 8, and examines whether image quality is appropriate or not, namely, whether processing conditions calculated by the first image processing section 7a are appropriate or not, and whether hue of the outputted image, contrast between a chromatic color and neutral, chroma and maximum lightness are appropriate or not, and the operator can input information indicating the results of the examination from operation section 11, through, for example, a key-correction.

Then, the operator judges whether the information indicating the results of the examination inputted through operation section 11 is information that means “success in examination” or not (step S16). When the information meaning “success in examination” is inputted (step S16: YES), the flow goes to step S24. When information giving instructions to correct image processing conditions, or information giving instructions to adjust chroma of the image is inputted as information indicating the results of the examination, the results of the examination by the operator are judged to be “failure in examination” (step S16: NO), and the flow goes to step S17.

In step S17, judgment is made to show which of hue of the image, contrast between a chromatic color and neutral, maximum lightness and chroma is indicated for adjustment, by information showing the inputted results of the examination. When information indicating correction of processing conditions of image processing other than color reproduction transform section is inputted (step S17: NO), a correction is made following the indications wherein processing conditions of image processing calculated in the step S13 are inputted, the corrected processing conditions are notified to the first image processing section 7a (step S18 ), and the flow returns to step S14.

Owing to this, processing to regenerate image data estimated by the corrected processing conditions is conducted in the first image processing section 7a, and image data generated again through estimation are outputted to CRT 8 through density transform by LUT 7b1 for density transform of color reproduction transform section 7b, whereby, an image based on the processing conditions corrected based on inputted instructions for correction is outputted and displayed again. By confirming visually the outputted image displayed on CRT 8 again, an operator can easily judge whether the contents of the instructions for correction inputted earlier are appropriate or not.

On the other hand, when adjustment for hue, contrast between a chromatic color and neutral, maximum lightness and chroma is judged to be improper or to be needed, for the outputted image displayed on CRT 8, an operator can acquire information (specifically, information to indicate an amount of adjustment and other information) for indicating adjustment of image hue, contrast between a chromatic color and neutral, maximum lightness and chroma through operation section 11. Incidentally, in the present embodiment, adjustment for hue, contrast between a chromatic color and neutral, maximum lightness and chroma can be set either to be increased or to be decreased. When the operator acquires information to indicate adjustment (step S17: YES), the flow goes to step S19.

In the step S19 and thereafter, there is conducted processing for adjusting each amount of characteristics of the image by 3D-LUT 7b2 for adjustment for hue, contrast, maximum lightness and chroma of color reproduction transform section 7b. However, prior to the explanation of this processing, respective adjustment data which are set on 3D-LUT 7b2 for adjustment when conducting color reproduction adjustment for the image by 3D-LUT 7b2 for adjustment of hue, contrast between a chromatic color and neutral, maximum lightness and chroma, will be explained.

On data storage section 80 connected to image processing section 70, there are stored (registered) previously adjustment data for hue, contrast between a chromatic color and neutral, maximum lightness and chroma which are for adjusting hue, contrast between a chromatic color and neutral, maximum lightness and chroma on the outputted image by 3D-LUT 7b2 for adjustment. These adjustment data are those which make RGB value of each pixel of image data before adjustment and RGB value of each pixel of image data after chroma adjustment to correspond each other, and change hue, contrast between a chromatic color and neutral, maximum lightness and chroma on the outputted image for each pixel, with a standard of an amount of adjustment, and for a pixel belonging to a prescribed color area, the aforesaid data can make the hue, contrast between a chromatic color and neutral, maximum lightness and chroma on the outputted image to be transform characteristics which transform image data so that hue, contrast between a chromatic color and neutral, maximum lightness and chroma changes can be transformed. In that case, adjustment data for these hue, contrast between a chromatic color and neutral, maximum lightness and chroma can be stored in data storage section 80 to be corresponded to transform data for image processing.

As shown in the following Tables 1, 2 and 3 as examples, the adjustment data are prepared through an output form of images and through an emphasis, an amount of compression and a method of transform for an amount of each characteristic of an image, and are stored in data storage section 80. Table 1 shows an example of the adjustment data of hue. Table 2 shows an example of the adjustment data for contrast between a chromatic color and neutral. Table 3 shows an example of the adjustment data for maximum lightness.

TABLE 1

| | | | | | | | | |
|---|---|---|---|---|---|---|---|---|
| | Hue | X0.6 | X0.6 | X0.6 | X0.8 | X0.8 | X0.8 | . . . |
| | compression | | | | | | | |
| | amount | | | | | | | |
| | Hue target | 50° | 50° | 50° | 45° | 45° | 45° | . . . |
| | angle | | | | | | | |
| | Compression | Even | Even | Uneven | Even | Even | Uneven | . . . |
| | by hue | | | | | | | |
| | Compression | Even | S- | S- | Even | S- | S- | . . . |
| | by chroma | | order | order | | order | order | |
| | . . . | . . . | . . . | . . . | . . . | . . . | . . . | . . . |
| Output | Print | DHP1 | DHP2 | DHP3 | DHP4 | DHP5 | DHP6 | |
| form | reflection- | | | | | | | |
| | type | | | | | | | |
| | Film | DHF1 | DHF2 | DHF3 | DHF4 | DHF5 | DHF6 | |
| | transmission- | | | | | | | |
| | type | | | | | | | |
| | Monitor | DH1 | DH2 | DH3 | DH4 | DH5 | DH6 | |
| | display | | | | | | | |
| | CD-R and | | | | | | | |
| | others | | | | | | | |

TABLE 2

| | | | | | | | | |
|---|---|---|---|---|---|---|---|---|
| | Contrast | 0.10 | 0.15 | 0.20 | 0.15 | 0.20 | 0.25 | . . . |
| | difference | | | | | | | |
| | Chromatic | X1.05 | X1.10 | X1.15 | X1.05 | X1.10 | X1.15 | . . . |
| | color gamma | | | | | | | |
| | N gamma | X0.95 | X0.95 | X0.95 | X0.9 | X0.9 | X0.9 | . . . |
| | Chroma | X1.2 | X1.2 | X1.2 | X1.5 | X1.5 | X1.5 | . . . |
| | emphasis | | | | | | | |
| | Emphasizing | Even | S- | S- | Even | S- | S- | . . . |
| | method | | order | order | | order | order | |
| Output | Print | DCP1 | DCP2 | DCP3 | DCP4 | DCP5 | DCP6 | |
| form | reflection- | | | | | | | |
| | type | | | | | | | |
| | Film | DCF1 | DCF2 | DCF3 | DCF4 | DCF5 | DCF6 | |
| | transmission- | | | | | | | |
| | type | | | | | | | |
| | Monitor | DC1 | DC2 | DC3 | DC4 | DC5 | DC6 | |
| | display | | | | | | | |
| | CD-R and | | | | | | | |
| | others | | | | | | | |

TABLE 3

| | | | | | | |
|---|---|---|---|---|---|---|
| | Lightness | ΔL*-5 | ΔL*-8 | ΔL*-5 | ΔL*-8 | . . . |
| | compression | | | | | |
| | amount | | | | | |
| | Hue of | — | — | +M | +M | . . . |
| | maximum | | | | | |
| | lightness | | | | | |
| | Highlight γ | — | — | −5% | −5% | . . . |
| | . . . | . . . | . . . | . . . | . . . | . . . |
| Output | Print | DMP1 | DMP2 | DMP3 | DMP4 | |
| form | reflection- | | | | | |
| | type | | | | | |
| | Film | DMF1 | DMF2 | DMF3 | DMF4 | |
| | transmission- | | | | | |
| | type | | | | | |
| | Monitor | DM1 | DM2 | DM3 | DM4 | |
| | display | | | | | |
| | CD-R and | | | | | |
| | others | | | | | |

Adjustment data for hue, contrast between a chromatic color and neutral, maximum lightness and chroma are established, for example, in a way explained as follows. First, relationship between a density value (hereinafter referred to as RGB value, simply) of each color component (RGB in this embodiment) on image data and L*a*b* on an outputted image in the case of outputting an image by the use of the image data (L*a*b* is a color system recommended by CIE as a uniform perceptual color space, and L* represents a lightness index, while, a*b* represents a degree of a perceptual color), is obtained for each output form. Specifically, patches each having each of various colors (colors each having a different color of a different combination of RGB values) are outputted as images, and measurement of L*a*b* of each patch on the outputted image by a measuring instrument is conducted for each output form.

With respect to the color for which the patch is not prepared, relationship between RGB values on the image data and L*a*b* values on the outputted image is obtained for the entire color reproduction area on the outputted image, by obtaining relationship between RGB values on the image data and L*a*b* values on the outputted image for each output form by the interpolation calculation. Due to this, relationship between L*a*b* values on the image data and L*a*b* values on the outputted image is obtained. It is also possible to obtain relationship between RGB values on the image data and L*a*b* values on the outputted image to use it.

Incidentally, 3D-LUT 7b2 for adjustment can also be constructed so that it stores all of L*a*b* values or RGB values after adjustment corresponding to all combinations of RGB values on the image data, as adjustment data, and it just reads out to output corresponding L*a*b* values or RGB values after adjustment when L*a*b* values or RGB values before adjusting hue, contrast between a chromatic color and neutral, maximum lightness and chroma, are inputted. In this case, however, there is a problem that a memory having huge storage capacity is needed as 3D-LUT 7b2 and data storage section 80, because a data amount of each adjustment data is huge.

Therefore, when adjustment data are constituted by thinning properly for L*a*b* and RGB values after adjustment of hue, contrast between a chromatic color and neutral, maximum lightness and chroma which correspond to all combinations of L*a*b* and RGB values on the image data, and when L*a*b* and RGB values after adjustment corresponding to inputted L*a*b* and RGB values before adjustment are not stored in 3D=LUT 7b2 as adjustment data, it is preferable to obtain color values after adjustment corresponding to color values before adjustment from color values after adjustment stored as adjustment data. Owing to this, it is possible to reduce storage capacity needed as 3D-LUT 7b2 and data storage section 80.

Then, an amount of adjustment for hue, contrast between a chromatic color and neutral, maximum lightness and chroma which is indicated when an operator operates operation section 11, is detected (step S19 ). After that, adjustment data among those stored in data storage section 80, which correspond to “monitor display/CD-R writing” and are adjustment data for hue, contrast between a chromatic color and neutral, maximum lightness and chroma, whose amount of adjustment agrees with the indicated amount of adjustment, are taken in (step S20 ).

In the present embodiment, in the case of “Adjustment Required” after results of scene discrimination and analysis, even in the case other than indication by an operator, in step S19, it is also possible to handle by calculating optimum combination by an amount of characteristics detected in step S12, and by detecting an amount of adjustment for hue, contrast between a chromatic color and neutral, maximum lightness and chroma.

Meanwhile, in the present embodiment, there may be an occasion where data agreeing with an amount of adjustment does not exist. In this case, it is also possible to handle in step S20 by taking in a plurality of adjustment data whose adjustment amount is close to the indicated amount of adjustment.

Then, a judgment is made on whether adjustment data whose corresponding adjustment amount agrees with the indicated adjustment amount are stored in data storage section 80 or not, namely, whether an interpolation calculation for adjustment data is necessary or not (step S21). When the interpolation calculation is not necessary (step S21: NO), the flow goes to step S23 without conducting any processing. When the interpolation calculation is necessary and plural adjustment data are taken in (step S21: YES), it is possible to obtain, based on plural adjustment data taken in, each adjustment data whose corresponding adjustment data agree with indicated adjustment amount, through interpolation calculation (step S22 ). Then, the adjustment data thus obtained are set in 3D-LUT 7b2 for adjustment for hue, contrast between a chromatic color and neutral, maximum lightness and chroma (step S23), and the flow goes to step S14.

Due to this, image data estimated by the first image processing section 7a is generated again, and regenerated image data are inputted in 3D-LUT 7b2 for adjustment of hue, contrast between a chromatic color and neutral, maximum lightness and chroma after being transformed in terms of density by LUT 7b1 for density transform of color reproduction transform section 7b. The image data thus inputted in 3D-LUT 7b2 for adjustment are transformed into image data after adjustment of hue, contrast between a chromatic color and neutral, maximum lightness and chroma, by the 3D-LUT 7b2 for adjustment for each pixel, and are outputted to CRT 8 to be displayed on CRT 8 as an adjusted outputted image.

When further adjustment of color reproduction transform is needed for each hue after determination of whether a color area for controlling color reproduction changes is indicated or not, it is also possible to arrange so that judgment of the foregoing and fine adjustment of data for adjustment are conducted at a step between step S23 and step S24, though the invention is not limited to this arrangement.

Adjustment data for hue, contrast between a chromatic color and neutral, maximum lightness and chroma set in 3D-LUT 7b2 for adjustment of chroma are data established based on a color reproduction range on an outputted image displayed on CRT 8 (in detail, based on relationship between RGB values on image data and L*a*b* values (values of L*C*H*) on an outputted image displayed on CRT 8), as stated above, which have transform characteristics for transforming image data, wherein: an amount of adjustment for corresponding hue, contrast between a chromatic color and neutral, maximum lightness and chroma agrees with each indicated amount of adjustment; in the pixel belonging to a prescribed color area (namely, a color area corresponding to a prescribed range of hue angle of 0-90°), a hue reproduction angle is compressed, or converged to a target hue angle determined specifically; the hue is transformed so that processing is conducted by changing a center of hue compression of a flesh color area and/or an amount of compression, following color temperature and white point; or compression is conducted greatly as an angle departs from a determined target hue angle, or compression is conducted slightly as chroma rises to be higher.

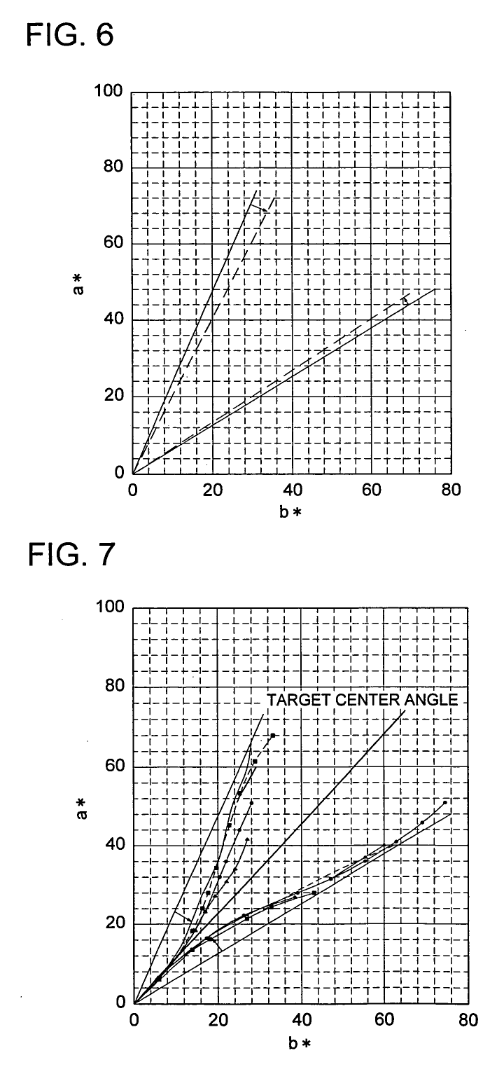

Now, an example of transform of the image data will be shown. FIG. 6 shows an example of compression of linear hue reproduction angle. As shown in FIG. 6, a hue reproduction angle of a range of a flesh color area corresponding to a flesh color of image data is compressed in the space of a* and b*. FIG. 7 shows an example of compression of nonlinear hue reproduction angle. As shown in FIG. 7, a hue reproduction angle was compressed on a nonlinear basis so that a range of a flesh color area may be converged to a specified and aimed target hue reproduction angle (center angle) and an extent of compression of the hue reproduction angle is made smaller as chroma C* increases, thus, reduction of hue deviation of a flesh color was observed in particular, and preferable color reproduction processing was carried out. It is further possible to enhance an extent of compression of the color reproduction angle as the angle departs from a target hue reproduction angle. It is also possible to change a center of compression of the hue reproduction angle of a range of a flesh color area and/or an amount of compression, based on color temperature and a maximum lightness.

Further, there are provided transform characteristics for transforming image data wherein contrast difference is emphasized by making contrast of neutral to be of a low contrast and by making contrast of other chromatic color to be of a high contrast, chroma is emphasized as lightness is lowered, an extent of chroma emphasis is emphasized as chroma grows greater, further, emphasis is carried out based on an amount of lightness changes, and if necessary, chroma and contrast are transformed so that lightness of a white point (maximum lightness) may be compressed to become low.

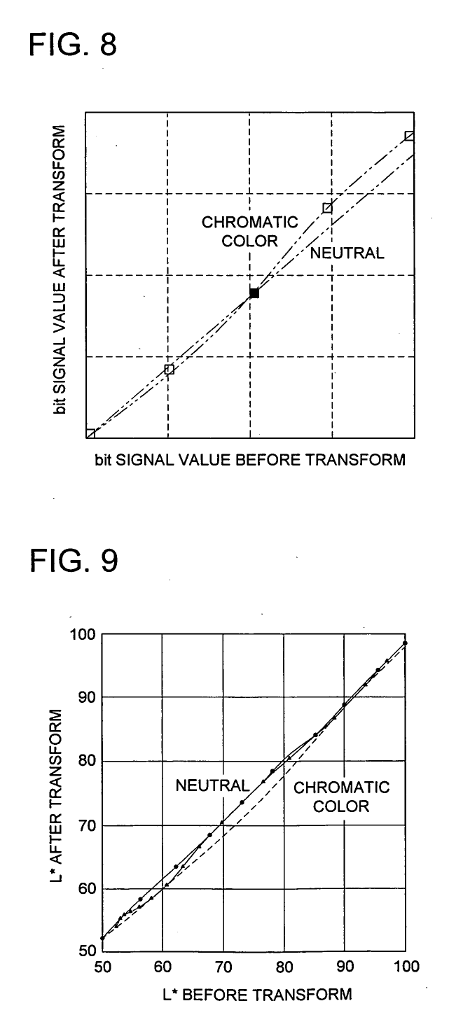

FIG. 8 shows an example of relationship between contrast (bit) between an achromatic color and a chromatic color before transform and contrast (bit) between an achromatic color and a chromatic color after transform. FIG. 9 shows an example of relationship between contrast (L*) between an achromatic color and a chromatic color before transform and contrast (L*) between an achromatic color and a chromatic color after transform. For example, with respect to the contrast between that before transform and that after transform, contrast of neutral was made to be low contrast and contrast of other chromatic colors was made to be high contrast as shown in FIG. 8 and FIG. 9. Owing to this, it was possible to give three-dimensional appearance and to obtain preferable color reproduction processing. Further, a difference between contrast of a chromatic color of image data and contrast of neutral may also be 5% or more.

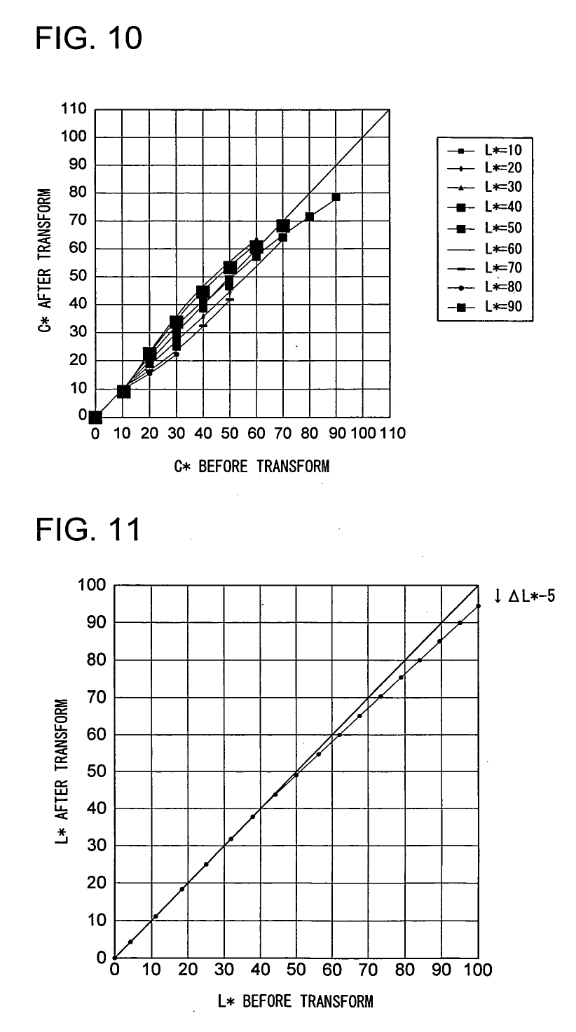

FIG. 10 shows an example of chroma transform. For example, a rate of chroma emphasis of image data after transform to chroma emphasis of image data before transform was emphasized more as the chroma grows greater as shown in FIG. 10. Due to this, color reproduction around the circumference shadow of a face was improved, resulting in preferable results. FIG. 11 shows an example of a lightness curve (contrast). For example, an extent of chroma emphasis of image data was emphasized based on amount of changes in lightness ΔL*, and lightness of maximum lightness (white point) after transform was made to be lower than that before transform. By lowering the maximum lightness and by compressing highlight, it was possible to obtain further preferable three-dimensional appearance even on the highlight.

Therefore, regarding an output image displayed on CRT 8, hue deviation on a flesh color is hardly caused when photographed on a portrait photograph basis, an expected color is stably reproduced, further, chroma around a shade is high and fine and three-dimensional appearance can be given, thus, a high-quality image resulted from the aforesaid processing can further be outputted optimally.

An operator examines whether or not an image quality has been improved properly by adjustment of hue, contrast between a chromatic color and neutral, maximum lightness and chroma indicated previously, by confirming visually the image displayed again on CRT 8. Then, when the operator judges that an amount of chroma adjustment is not appropriate, for example, the operator inputs information for correcting the amount of chroma adjustment indicated previously, through key correction included in operation section 11. Owing to this, a judgment in step S16 is denied and a judgment in step S17 is affirmed, and processing operations for S19-S23 are repeated based on a new amount of chroma adjustment after correction.

In examination of the output image, when an operator judges that there are some portions where image quality is deteriorated by excessive magenta in hue of a skin, although an amount of chroma adjustment for the entire image is appropriate, the operator can operate operation section 11 for changing an amount of hue compression of the aforesaid portions and a target angle to attempt to improve the image quality.

In examination of the output image, when an operator judges that three-dimensional feeling on the entire image is insufficient and there are some portions where image quality is deteriorated, because of insufficient difference of contrast between a chromatic color and neutral, although an amount of chroma adjustment for the entire image is appropriate, the operator can operate key correction of changes in contrast between a chromatic color and neutral on the aforesaid portions, through operation section 11, to adjust and to attempt to improve the image quality.

Further, similarly to the foregoing, when an operator judges that there are some portions where image quality is deteriorated by excessive chroma changes (increase), although an amount of chroma adjustment for the entire image is appropriate, in examination of the output image, the operator can operate key correction of chroma changes on the aforesaid portions, through operation section 11, to adjust chroma changes and to attempt to improve the image quality.

In the present embodiment, there is no limitation to the aforesaid image processing method, and for easy adjustment of hue, contrast between a chromatic color and neutral, maximum lightness and chroma, and for easy designation of that color area, for example, it is possible to divide a color reproduction range on the output image into plural divisional color areas in advance by classifying hue angle H*, chroma C* and lightness L* into plural ranges (for example, classifying into 3 steps of high/medium/low, or classifying more finely), whereby, an operator can operate through operation section 11 to select a color area to be changed from the plural divisional color areas to designate adjustment of an amount of changes.

Further, even for designation of an extent of changes, it is possible to arrange to divide into plural steps (for example, high/medium/low) so that an operator can designate by selecting the step corresponding to the desired extent of control from the plural steps, through operation section.

When an operator desires adjustment on the selected color area, it is possible to arrange so that adjustment data which are set presently in 3D-LUT 7b2 for adjustment are read out when information is inputted, and the flow moves to step S23 after the adjustment data read out are corrected so that changes on the output image on the designated color area may become transform characteristics corresponding to the designated extent.

When an operator judges image quality of the output image displayed on CRT 8 to be appropriate, and inputs information that means “success in examination” as information indicating examination results, the results of the examination by the operator are judged to be “success in examination” (step S16: YES), and information indicating the decided processing conditions (the latest processing conditions notified to the first image processing section 7a) is stored temporarily in data storage section 80 to be corresponded to image discrimination information (for example, frame number) for discriminating the target image (step S24).

Then, there is judged whether adjustment was indicated by an operator in the course of image examination or not (step S25). When adjustment was not indicated (step S25; NO), image adjustment processing is terminated without doing any processing. When adjustment was indicated by an operator in the course of image examination (step S25; YES), an output form for outputting images is judged based on output form designating information attached to the stored image data, and a judgment is made whether the output form is on “print output” or not (step S26).

When the output form in the case of outputting images is on “print output” in step S25, a color reproduction area on the output image is different from a color reproduction area on the output image displayed on CRT 8 in the course of image examination, and therefore, an output image displayed is not reproduced on an outputted object, resulting in a possibility of image quality deterioration such as lacking detail and others on the image outputted.

When outputting images without considering whether a medium for image outputting is of a reflection type or of a transmission type, or without considering a density range and a color area of the medium, further improvement of image quality cannot be expected. On the other hand, there is further a difference in output device characteristics such as an inkjet type and a sublimation type printer. If there is given no color management of an image for output between an output medium and an output device as these image output means, there is a possibility of image quality deterioration such as color saturation and others on the image which is outputted in the same way.

Therefore, when the output form is on “print output” (step S26; YES), a judgment is further made whether adjustment of gamut (color) mapping in the case of outputting was indicated by an operator in the course of image examination or not (step S27).

When adjustment of gamut mapping is not indicated (step S27; NO), an amount of adjustment decided finally in the course of image examination is detected in the same way as in step S19-S23 explained earlier, without conducting any image processing, and adjustment data wherein corresponding amount of adjustment agrees with or is close to the detected amount of adjustment among adjustment data for “print output” stored in data storage means 80 are read from data storage section 80, whereby, adjustment data wherein corresponding amount of adjustment agrees with the detected amount of adjustment are obtained by conducting interpolation calculation if necessary (step S28).

When adjustment of gamut mapping is indicated (step S27; YES), an output form in the case of outputting images is judged based on output form indication information attached to the stored image data, and characteristics of an output device and a medium (color gamut information) are detected (step S30). Meanwhile, this corresponds to transforming of output image data subjected to image processing into output color image signals based on characteristics of image output section.

Then, 3D-LUT 7b3 for output adjustment representing the indicated gamut mapping adjustment data is taken in from data storage section 80 for conducting image transform (step S31). When a plurality of adjustment data are taken in step S31, calculation processes wherein each adjustment data in which the corresponding amount of adjustment agrees with the indicated amount of adjustment is combined, can be unitized into one, based on the plural adjustment data taken in.

In the meantime, using gamut mapping adjustment data as stated above corresponds to using them as the third function of the standard color space including the first transform function that transforms input color image signals of image data into signals in the standard color space based on characteristics of the image input section and the second transform function that transforms signals in the standard color space into output color image signals based on characteristics of the image output section.

Now, Table 4 shows an example of gamut mapping adjustment data.

TABLE 4

| | | | | | | | | |
|---|---|---|---|---|---|---|---|---|
| | Compression | Perceptive | Perceptive | Perceptive | Perceptive | Absolute | Relative | . . . |
| | method | | | | | value | value | |
| | Compression | High | High | Uniform | High | High | High | . . . |
| | map | chroma | chroma | | chroma | chroma | chroma | |
| | | Uneven | Uneven | | Uneven | Uneven | Uneven | |
| | Medium | Chroma of | Chroma of | Chroma of | Chroma of | — | Chroma | . . . |
| | color area | low | low | low | low | | of low | |
| | | lightness | lightness | lightness | lightness | | lightness | |
| | | Expansion | Expansion | Expansion | Expansion | | Expansion | |
| | Neutral | *2 | *2 | *2 | — | *2 | *2 | . . . |
| Output | Print | DGP1 | DGP2 | DGP3 | DGP4 | DGP5 | DGP6 | |
| form | reflection- | | | | | | | |
| | type | | | | | | | |
| | *1 | DGF1 | DGF2 | DGF3 | DGF4 | DGF5 | DGF6 | |
| | Inkjet and | DGJ1 | DGJ2 | DGJ3 | DGJ4 | DGJ5 | DGJ6 | |
| | others | | | | | | | |

*1: Film transmission-type
*2: Maintenance

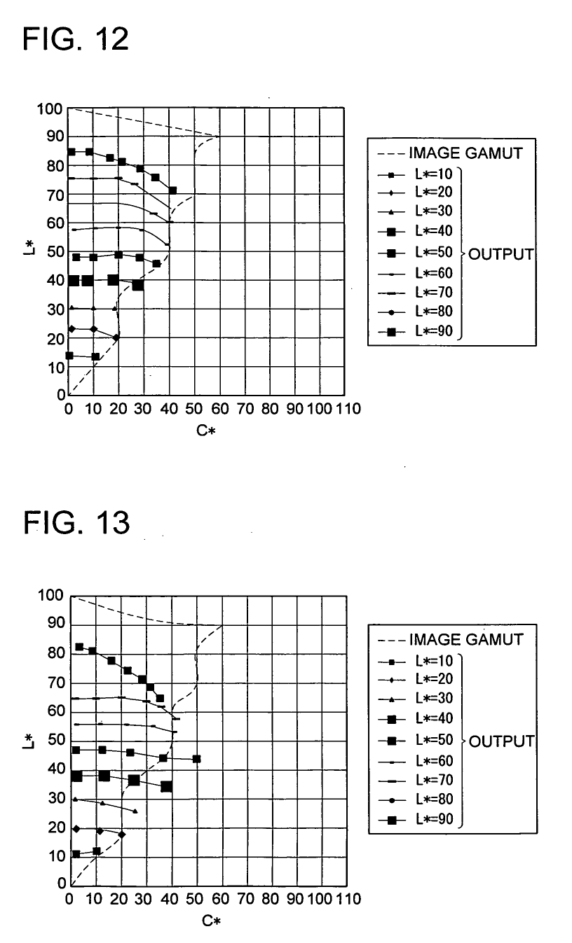

Now, an example of gamut mapping in the present embodiment will be explained. FIG. 12 shows a comparative example (conventional example) of gamut mapping. FIG. 13 shows an example of gamut mapping. An example of gamut mapping of the present embodiment shown in FIG. 13 made it possible to obtain a preferable outputted object having massive feeling similar to that of an analogue photograph, by conducting color mapping on a color area that is not used in FIG. 12 and by outputting, in the case of outputting image data after color reproduction processing of steps S19-S23.

More preferably, conducting image processing causing no saturation of chroma changes by using a color area broader than that of image data before transform, based on a-color reproduction range in the output form of image data, is preferable because it can prevent tone jump and a pseudo contour.

When it is indicated to select an optimum output by that of gamut mapping, in addition to printer-specific processing, in the case of output in step S31 as stated above, adjustment data are corrected so that an amount of adjustment on the output image may be equal to an amount of adjustment of designated color management. Owing to this, it is possible to obtain image adjustment data which can make image quality of the image to be outputted to be the same as or higher than that of the image displayed on CRT 8.

As stated above, a point of maximum lightness of image data in the case of outputting a reflection-type print formed through subtractive color mixture is made to be lower than that of image data for a transmission-type image formed through additive color mixture and/or a visible image on the monitor; image data are transformed into output,color image signals based on characteristics of an image output device; a profile of an image inputting section and a profile of an output target are held, and a transform expression for bringing close to the target color reproduction is prepared based on the inputting profile and the target profile; the first transform function that transforms input color image of image data into signals in the standard color space based on characteristics of an image input section, the second transform function that transforms signals in the standard color space based on characteristics of an image output section and the third function that transforms the signals processed by second function into output color image signals are used, in the case of outputting after conducting image processing; and image processing is conducted by using a color area that is broader than a color area of image data before-processing so that chroma changes may not be saturated, based on the color reproduction range in the output system. Owing to the foregoing, it is possible to generate optimum image data wherein hue deviation for flesh color is hardly caused when photographing on a portrait photograph basis, an expected color is reproduced stably, chroma around a shade is high and fine, and three-dimensional appearance can be obtained in outputting, output image having three-dimensional appearance and massive feeling which are the same as those of a conventional analogue photograph can be obtained, and no problem is caused even when outputting image data on a transmission-type positive film or CRT output, and on reflection type color paper.

Then, chroma adjustment data for high resolution image data decided in step S28 or S31 or in the preceding step are stored in data accumulation section 80 (step S29) to be corresponded to image discrimination information and processing condition information which are stored temporarily in data accumulation section 80 in the preceding step S24, thus, image adjustment processing is terminated.

Incidentally, after the image adjustment processing is terminated, high resolution image data of images to be outputted in the designated predetermined output form are taken in from film scanner 9, and image processing section 70 reads out the processing condition information from data accumulation section 80 based on image discrimination information of images expressed by high resolution image data, and it outputs the processing condition information thus read out to the image processing section 70, to instruct practice of image adjustment processing.

Then, image data which have been subjected to color reproduction transform-processing by image processing section 70 and color reproduction transform section 7b are either outputted to an output device corresponding to predetermined output style, or written in CD-R by image writing section 15.

Concerning images which are adjusted in terms of hue, contrast between chromatic color and neutral, maximum lightness and chroma, at the time of examination, image transform processing is conducted by 3D-LUT 7b2 for color adjustment and 3D-LUT 7b3 for output adjustment in terms of hue, contrast between chromatic color and neutral, maximum lightness and chroma, based on data adjusted by color reproduction transform section 7b (based on adjustment data identical to respective adjustment data used in image examination, if an output style is “monitor display/CD-R writing” and based on data for print output corresponding to adjustment data used in image examination, if an output style is “print output”).

Therefore, in the photographic market and even in the image market, it is possible to provide an image processing apparatus, an image processing method and an image processing system which can transform into image data wherein hue deviation for flesh color is hardly caused when photographing on a portrait photograph basis, an expected color is reproduced stably, chroma around a shade is high and fine, and three-dimensional appearance can be given, further, a high quality image processed in the aforesaid way can be outputted optimally, and an output image having three-dimensional appearance and massive feeling which are the same as those of a conventional analogue photograph can be obtained.

It is further possible to obtain an effect to generate image data for outputting on a transmission-type positive film or on CRT, and to generate optimum image data which cause no problem even when outputting of a reflection-type color paper.

Incidentally, in image processing of the present embodiment, image processing can also be conducted on image data for outputting on a medium of silver halide. Further, compression of a hue reproduction angle in a flesh color area of image data of a person may also be made greater than that in image data for a still-life image.

### Second Embodiment

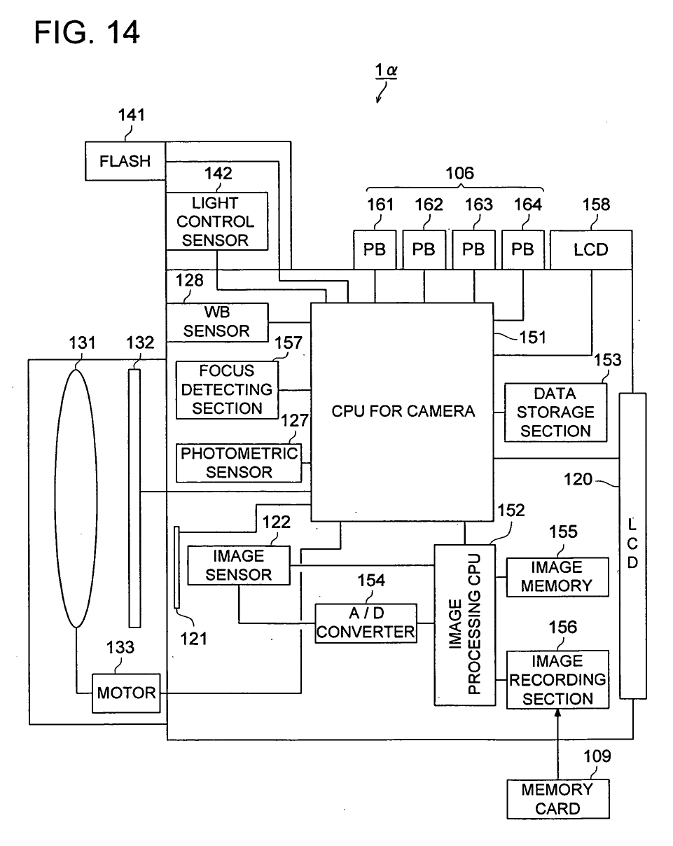

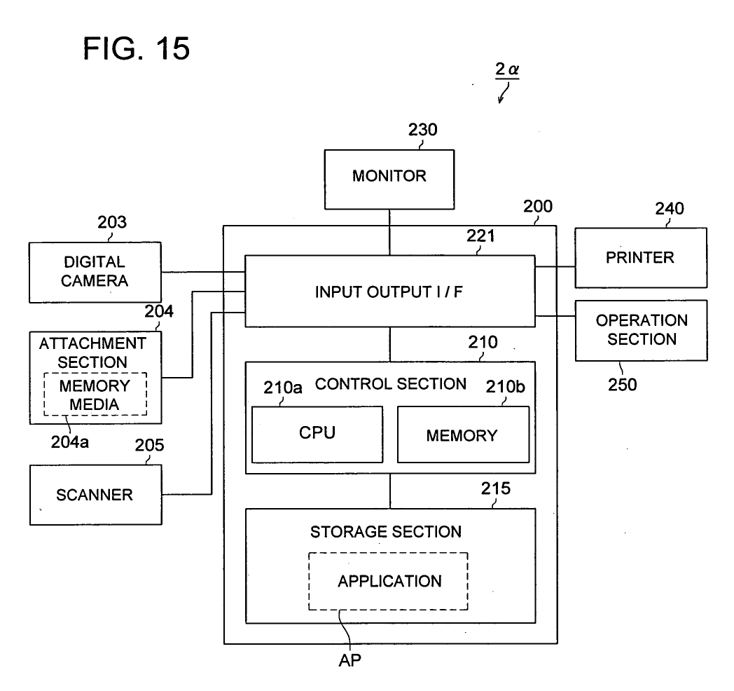

The second embodiment relating to the invention will be explained with reference to FIG. 14. FIG. 14 shows an inner structure of digital camera 1a of the present embodiment. Digital camera 1α serving as a photographing apparatus of the present embodiment is one wherein the image processing function explained in the First Embodiment is incorporated to the digital camera described in Unexamined Japanese Patent Application Publication No. 2001-275122.

The digital camera 1α a has therein CPU 151 for camera that controls various portions and CPU 152 for image processing. The CPU 151 for camera is connected electrically to focal plane shutter 121, focus detecting section 157 that detects a focus position with information coming from photometric sensor 127, WB (white balance) sensor 128, diaphragm 132 and LCD 120. The CPU 151 for camera is connected electrically to flash 141, light control sensor 142, lens motor 133 that changes a position of image-taking lens 131, data storage section 153 that is composed of EEPROM, display section 158 that displays photographing conditions on a liquid crystal display and operation section 106. This operation section 106 has therein shutter button 161, WB selecting button 162, exposure mode selecting button 163 and auto-focusing selecting button 164. The CPU 151 for camera is linked with the aforesaid various sections organically, to control photographing operations in digital camera 1α.

The CPU 152 for image processing is connected electrically with image sensor 122 and is connected with A/D converter 154 that transforms analogue signals coming from the image sensor 122 into digital signals. The CPU 152 for image processing is further connected electrically with image memory 155 in which photographed images are preserved temporarily, and with image recording section 156 for recording final output image subjected to image processing on memory card 109.

This CPU 152 for image processing conducts various image processing including drive control and output reading out of image sensor 122, white balance correction, Y transform and digital filter. Further, respective CPUs 51 and 52 are arranged so that they may conduct correspondence of data each other in case of need.

As a function identical to the color reproduction transform section 7b of the first embodiment, a computation section that adjusts hue, contrast between chromatic color and neutral, maximum lightness and chroma is installed on CPU 152 for image processing, and on digital camera 1α, various modes such as a portrait mode, a still-life mode, an automatic mode and a manual mode which can select image processing for each photographing scene can be selected before photographing and can be stored in data storage section 153, in addition to the mode for adjusting white balance of image data obtained through photographing.

Now, photographing operations of digital camera 1 will be explained briefly. First, before photographing, image-taking lens 131 is moved in the axial direction by operations of operation section 106 by an operator, then, diaphragm 132 is adjusted and whereby, a focal point and an aperture diameter are determined. Images which have entered through image-taking lens 131 are read by image sensor 122 to be transformed into analogue signals, then, the analogue signals are transformed into digital imaging data by A/D converter 154, and are subjected to image processing by CPU 152 for image processing to be transformed into image data, and the image data are displayed on LCD 120. Before photographing, various adjustment data including white balance are adjusted by operation section 106.

Then, a focal point is fixed by half-pressing operations on shutter button 161 by a user, and imaging data taken by focal plane shutter 121, image sensor 122 and A/D converter 154 are subjected to image processing by CPU 152 for image processing based on adjustment data adjusted before photographing, to be converted into image data, and the image data are stored in image memory 155. For photographing, flash 141 is used arbitrarily. The image data stored in image memory 155 are preserved in the data storage section 153 by operations on operation section 106, and are stored in memory card 109 by image recording section 156.

Now, image processing of the CPU 152 for image processing will be explained as follows. In the CPU 152 for image processing, image processing is selected as follows by a photographing scene mode selected before photographing, and imaging data are transformed on a color reproduction basis. In the case of a portrait mode, a color reproduction transforming section in the CPU 152 for image processing adjusts hue, contrast between a chromatic color and neutral, maximum lightness and chroma. In the case of a still-life mode, the aforesaid color reproduction transforming section in the CPU 152 for image processing judges for designation whether color reproduction processing should be added or not, and only when it is judged to be added, the color reproduction transforming section adjusts contrast between a chromatic color other than that of hue compression and neutral, maximum lightness and chroma.

Further, these adjustment parameters are of the functions which can edit and arrange with internal data, or can edit with an external computer and can let data storage section 153 read to be reflected on CPU 152 for image processing. As a result, it is possible to provide a photographing apparatus that transforms into image data wherein hue deviation on a flesh color is hardly caused when photographed on a portrait photograph basis, an expected color is stably reproduced, further, chroma around a shade is high and fine and three-dimensional appearance can be given, and a high-quality image resulted from the aforesaid processing can further be outputted optimally, thus, an output image having three-dimensional appearance and substantial feeling which are the same as those of a conventional analogue photograph can be obtained naturally in the photographic market and even in the image market. Further, even in the case of the still-life mode, it is possible to make chroma to be high and fine and to be hardly affected by environmental variations, and to give three-dimensional appearance and substantial feeling which are the same as those of a conventional analogue photograph.

### Third Embodiment

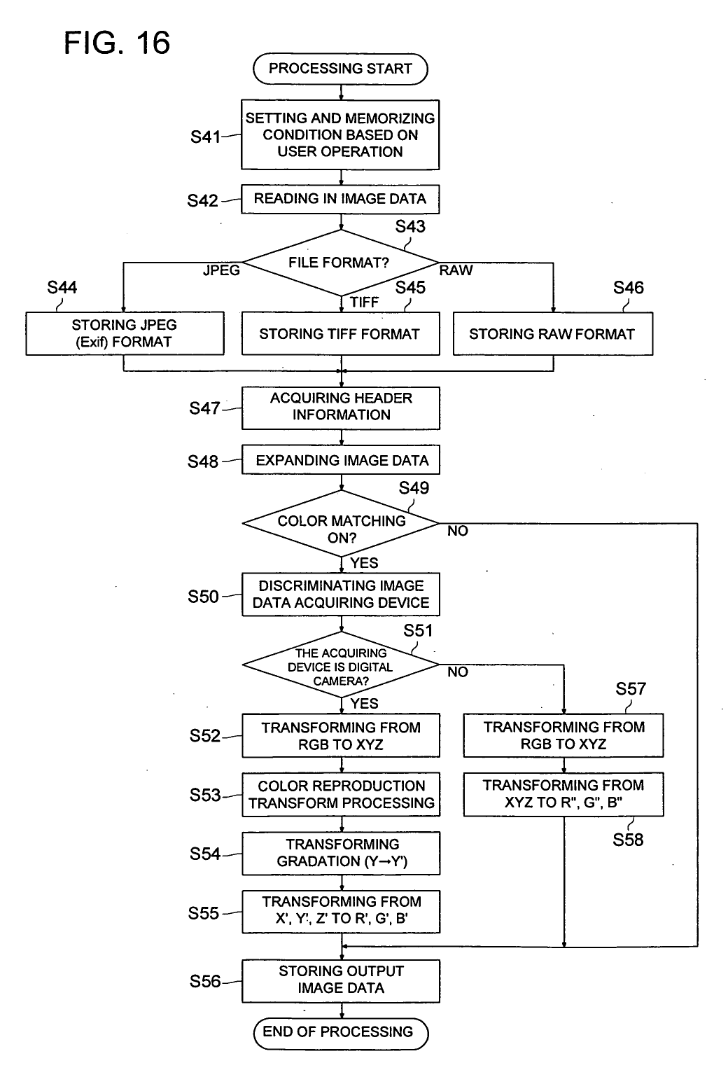

The third embodiment relating to the invention will be explained with reference to FIGS. 15 and 16. FIG. 15 shows an inner structure of image processing system 2α of the present embodiment. Application AP serving as an image processing program of the present embodiment is of the structure wherein an application (program) practiced in the image processing system described in Unexamined Japanese Patent Application Publication No. 2003-299116, for example, makes the image processing function explained in the First Embodiment to be realized on a computer.

As shown in FIG. 15, image processing system 2α of the present embodiment is provided with digital camera 203 for inputting image data, attachment section 204 scanner 205, personal computer 200 capable of transmitting data through communication cable, monitor 230 and printer 240 both connected to personal computer 200 to be capable of transmitting data and with operation section 250.

Personal computer 200 is equipped with control section 210, storage section 215 and input output I/F 221. The input output I/F 221 includes digital camera 203, attachment section 204, scanner 205, monitor 230, printer 240 and operation section 250, and conducts transmitting and receiving of data between itself and control section 210.

The storage section 215 is composed, for example, of a hard disc, and it stores application AP which will be described later. Control section 210 has therein CPU 210 a and memory 210b, and it is a portion to unify and control various portions of personal computer 200. Image processing (which will be described later) can be carried out by loading application (program) AP stored in the storage section 215 on memory 210b of the control section 210 to be practiced by CPU 210a, and the control section 210 works as “an image processing apparatus”.

The digital camera 203 is an ordinary digital camera, while, memory media 204 a can be mounted on the attachment section 204, and image data stored in the memory media 204 a are transmitted to input output I/F 221. The scanner 205 is an ordinary film scanner, and a color film on which dye density is recorded through photographing by a silver halide camera is set on the film scanner so that image data may be acquired to be transmitted to input output I/F 221.

The monitor 230 is composed, for example, of CRT and is capable of displaying an image based on output image data generated in control section 210. The printer 240 prints an image based on output image data generated by the control section 210. The operation section 250 is composed of a key board and a mouse, and it transmits various electric signals to input output I/F 221 through respective operations.

The CPU 210a for image processing is loaded with a computation section that adjusts hue, contrast between a chromatic color and neutral, maximum lightness and chroma, as a function identical to color reproduction transform section 7b of the First Embodiment.

Next, with reference to FIG. 16, there will be explained operations of image processing which conform to application AP in control section 210 of image processing system 2α. FIG. 16 shows image processing. These operations are practiced when application AP stored in storage section 215 is read into memory 210b in control section 210 to be started. Incidentally, in this case, let it be assumed that image data are under the condition to be capable of being inputted in input output I/F 221 from at least one of digital camera 203, memory media 204a and scanner 205, before starting of application AP.

In this case, input image data ID are inputted in control section 210 through input output I/F 221 from any one of digital camera 203, memory media 204a and scanner 205 connected to personal computer 200, based on operations on operation section 250 by a user, after application AP is started. Then, image processing conditions are displayed on monitor 230, and image processing conditions are established, based on various operations on operation section 250 by a user, to be stored in memory 210b (step S41). Conditions to be established include equipment to be acquired and color matching, and information to be set such as modes including a portrait mode, a still-life mode, an automatic mode and a manual mode which were explained in the Second Embodiment.

Then, input image data ID are read in (step S42), and an image file style relating to the input image data ID thus read in is discriminated (step S43). If a file style of the input image data ID is JPEG (Exif) style (step S43; JPEG), memory 210b stores that a file style of input image data ID is JPEG style (step S44). Also in steps S45 and S46, memory 210b stores equally that a file style of input image data ID is a TIFF style or a RAW style respectively.

Then, following a file style of the input image, header information of image file is obtained and stored in memory 210b (step S47). When a file style of the input image is one other than a RAW style, input image data which are read in step S42 are developed (extended) (step S48). Then, based on establishment conditions inputted in step S41, or based on header information in input image data ID (or, profile information stored in memory 210b corresponding to the header information), color matching processing is judged whether it should be conducted or not (step S49). When color matching processing is conducted (step S49; YES), an equipment by which input image data ID were obtained is discriminated, based on establishment conditions inputted in step S41 (step S50).

Then, based on the results of the discrimination in step S50, an equipment acquiring input image data ID is judged whether it is a digital camera or not (step S51). When the equipment acquiring input image data ID is judged to be a digital camera (step S51; YES), image data relating to the input image data ID is transformed into image data of the XYZ color system from image data of RGB color system (step S52). Then, the color reproduction transform processing (image processing) explained in the First Embodiment is applied on the image data of the XYZ color system transformed in step S52 (step S53). In step S53, when a mode is a portrait mode, for example, hue, contrast between a chromatic color and neutral, maximum lightness and chroma are adjusted, as a color reproduction transform section of control section 210. In the case of a still-life mode, after judgment and designation for whether color reproduction processing should be added or not, contrast between a chromatic color other than that of hue compression and neutral, maximum lightness and chroma are adjusted, only when the processing is needed.

Gradation characteristic transform (gradation transform) is conducted on image data of the XYZ color system on which the color reproduction transform processing was conducted in step S53 (step S54). This gradation characteristic transform transforms into image data (X′Y′Z′) of the XYZ color system. Then, the transformation from image data (X′Y′Z′) of the XYZ color system to image data (R′G′B′) of the RGB color system is carried out (step S55).

When the equipment acquiring input image data ID is judged not to be a digital camera (step S51; NO), image data relating to the input image data ID is transformed into image data of the XYZ color system from image data of RGB color system, in the same way as in step S52 (step S57). Then, image data (XYZ) of the XYZ color system are transformed into image data (R″G″B″) of the RGB color system conforming to an image output section, in the same way as in step S55 (step S58). Then, input image data which have been or have not been subjected to image processing are stored in memory 210b as output image data (step S56), and image processing is terminated.

In the present embodiment, it was possible to provide an application program which can transform into image data wherein hue deviation for flesh color is hardly caused when photographing on a portrait photograph basis, an expected color is reproduced stably, chroma around a shade is high and fine, and three-dimensional appearance can be given, further, a high quality image processed in the aforesaid way can be outputted optimally, and an output image having three-dimensional appearance and massive feeling which are the same as those of a conventional analogue photograph can be obtained naturally in the photographic market and even in the image market. Further, even in the case of the still-life mode, it was possible to make chroma to be high and fine around the shade and to be hardly affected by environmental variations, and to give three-dimensional appearance and substantial feeling which are the same as those of a conventional analogue photograph.

Further, these adjustment parameters can be made to be edited and arranged in control section 210 of application AP, and thereby to be of the structure to function as CPU 52 for image processing.

Incidentally, the description in the aforesaid embodiment is an example of each of an image processing apparatus, an image processing system, a photographing apparatus, an image processing method and a program which are related to the invention and are preferable, and the invention is not limited to them. With respect to the detailed structures and detailed operations of respective constituent elements for the image processing apparatus, the image processing system, the photographing apparatus, the image processing method and the program in the aforesaid embodiment, they may naturally be modified or varied without departing from the spirit and scope of the invention.

Availableness in Industry

In the present invention, when a range of a flesh color area of image data is compressed, changes of hue under environmental light can be controlled, partial decline of image quality caused by changes in hue of visible images can be controlled effectively, and image data can be made to be appropriate for color reproduction. For example, hue deviation for a flesh color is hardly caused on image data obtained through photographing on a portrait photograph basis, and expected colors can be reproduced stably.

By making the contrast of a chromatic color to be high after image processing, and by making the contrast of neutral to be low, it is possible to obtain illusion-caused three-dimensional appearance that is preferable for a portrait, and to improve image quality, and thereby to make image data to be of appropriate color reproduction.

It is possible to realize appropriate color reproduction by making visible image data for a transmission-type film formed through additive color mixture and/or the monitor to correspond to image data for a reflection-type print formed through subtractive color mixture, by lowering maximum lightness of image data for a reflection-type print formed through subtractive color mixture, compared with visible image data for a transmission-type film formed through additive color mixture and/or the monitor.

1. An image processing apparatus comprising an image processing section which conducts image processing on image data, wherein the image processing section compresses a hue reproduction angle in a range of flesh color area corresponding to a flesh color in the image data.

2. The image processing apparatus of claim 1, wherein the image processing section compresses the hue reproduction angle in a range of flesh color area such that the range of flesh color area is converged to a target hue reproduction angle specified as a target.

3. The image processing apparatus of claim 1, wherein the image processing section changes a center of a compressed hue reproduction angle in a range of the flesh color area and/or an amount of compression, based on a color temperature and a white point of illumination light at image data generation.

4. The image processing apparatus of claim 1, wherein the image processing section enhances a degree of the compression of the hue reproduction angle as an angle of the image data recedes from the target hue reproduction angle, in the case of converging the range of the flesh color area to the target hue reproduction angle determined specifically.

5. The image processing apparatus of claim 1, wherein, the image processing section decreases a degree of compression of the hue reproduction angle as chroma of the image data becomes higher.

6. An image processing apparatus comprising an image processing section which conducts image processing on image data, wherein the image processing section makes a contrast of neutral color image data to be low contrast, and makes a contrast of chromatic color image data to be high contrast.

7. The image processing apparatus of claim 6, wherein the image processing section makes a difference between the contrast of chromatic color image data and the contrast of neutral color image data to be 5% or more.

8. The image processing apparatus of claim 6, wherein the image processing section emphasizes chroma of the image data more as lightness of the image data becomes lower.

9. The image processing apparatus of claim 6, wherein the image processing section increases a degree of chroma emphasis for the image data as chroma of the image data becomes greater.

10. The image processing apparatus of claim 6, wherein the image processing section increases a degree of chroma emphasis for the image data depending on an amount of changes in lightness of the image data.

11. The image processing apparatus of claim 6, wherein the image processing section lowers maximum lightness of the image data after image processing to be lower than maximum lightness of the image data before image processing.

12. The image processing apparatus of claim 6, wherein the image processing section compresses a hue reproduction angle in a range of a flesh color area corresponding to a flesh color in the image data.

13. The image processing apparatus of claim 1, wherein the image data to be subjected to the image processing are scene-referred data in the course of photographing and/or RAW data.

14. An image processing apparatus comprising an image processing section which conducts image processing on image data such that maximum lightness of image data for a reflection-type print formed through subtractive color mixing is lowered, compared to image data for a transmission-type film formed through additive color mixture or for a visible image on a monitor.

15. The image processing apparatus of claim 1, wherein the image processing section transforms image data subjected to the image processing into output color image signals based on characteristics of an image outputting section.

16. The image processing apparatus of claim 1, wherein the image processing section comprises:
a first transform section which transforms input color image signals of the image data into signals in a standard color space based on characteristics of an image inputting section;
a second transform section which transforms the signals in the standard color space based on characteristics of an image outputting section; and
a third transform section which transforms signals in the standard color space having been transformed by the second transform section into output color image signals.

17. The image processing apparatus of claim 1, wherein the image processing section conducts image processing based on a color reproduction range of an output system of the image data such that the image processing causes no saturation of chroma changes by using a broader color gamut than a color gamut of the image data before image processing.

18. The image processing apparatus of claim 1, wherein the image processing section conducts image processing on the image data which holds a profile of an image inputting section.

19. The image processing apparatus of claim 1, wherein the image processing section conducts image processing on the image data for outputting on a silver halide medium.

20. The image processing apparatus of claim 1, wherein the image processing section compresses a hue reproduction angle more greatly in a flesh color area of human image data, compared with still life image data.

21. The image processing apparatus of claim 1, wherein the image processing section conducts scene discrimination and/or face image extraction, and changes a transformation condition for the image processing based on results of the scene discrimination and/or the face image extraction.

22. An image photographing apparatus comprising:
a photographing section to create image data by photographing a photographic object; and
an image processing apparatus of claim 1, wherein the image processing section conducts image processing for image data created by the photographing section.

23. An image processing system comprising:
an image input section to input image data;
an image output section to output image data; and
an image processing apparatus of claim 1, wherein the image processing apparatus conducts image processing on image data inputted from the image input section, and outputs the image data to the image output section.

24. An image processing method for conducting image processing on image data, comprising an image processing step to compress a hue reproduction angle in a range of flesh color area corresponding to a flesh color in the image data.

25. The image processing method of claim 24, wherein the image processing step compresses the hue reproduction angle in a range of flesh color area such that the range of flesh color area is converged to a target hue reproduction angle specified as a target.

26. The image processing method of claim 24, wherein the image processing step changes a center of a compressed hue reproduction angle in a range of the flesh color area and/or an amount of compression, based on a color temperature and a white point of illumination light at image data generation.

27. The image processing method of claim 24, wherein the image processing step enhances a degree of the compression of the hue reproduction angle as an angle of the image data recedes from the target hue reproduction angle, in the case of converging the range of the flesh color area to the target hue reproduction angle determined specifically.

28. The image processing method of claim 24, wherein, the image processing step decreases a degree of compression of the hue reproduction angle as chroma of the image data becomes higher.

29. An image processing method comprising an image processing step to conduct image processing on image data, wherein the image processing step makes a contrast of neutral color image data to be low contrast, and makes a contrast of chromatic color image data to be high contrast.

30. The image processing method of claim 29, wherein the image processing step makes a difference between the contrast of chromatic color image data and the contrast of neutral color image data to be 5% or more.

31. The image processing method of claim 29, wherein the image processing step emphasizes chroma of the image data more as lightness of the image data becomes lower.

32. The image processing method of claim 29, wherein the image processing step increases a degree of chroma emphasis for the image data as chroma of the image data becomes greater.

33. The image processing method of claim 29, wherein the image processing step increases a degree of chroma emphasis for the image data depending on an amount of changes in lightness of the image data.

34. The image processing method of claim 29, wherein the image processing step lowers maximum lightness of the image data after image processing to be lower than maximum lightness of the image data before image processing.

35. The image processing method of claim 29, wherein the image processing step compresses a hue reproduction angle in a range of a flesh color area corresponding to a flesh color in the image data.

36. The image processing method of claim 24, wherein the image data to be subjected to the image processing are scene-referred data in the course of photographing and/or RAW data.

37. An image processing method comprising an image processing step to conduct image processing on image data such that maximum lightness of image data for a reflection-type print formed through subtractive color mixing is lowered, compared to image data for a transmission-type film formed through additive color mixture or for a visible image on a monitor.

38. The image processing method of claim 24, wherein the image processing step transforms image data subjected to the image processing into output color image signals based on characteristics of an image outputting section.

39. The image processing method of claim 24, wherein the image processing step comprises:
a first transform step to transform input color image signals of the image data into signals in a standard color space based on characteristics of an image inputting section;
a second transform step to transform the signals in the standard color space based on characteristics of an image outputting section; and
a third transform step to transform signals in the standard color space having been transformed by the second transform step into output color image signals.

40. The image processing method of claim 24, wherein the image processing step conducts image processing based on a color reproduction range of an output system of the image data such that the image processing causes no saturation of chroma changes by using a broader color gamut than a color gamut of the image data before image processing.

41. The image processing method of claim 24, wherein the image processing step conducts image processing on the image data which holds a profile of an image inputting section.

42. The image processing method of claim 24, wherein the image processing step conducts image processing on the image data for outputting on a silver halide medium.

43. The image processing method of claim 24, wherein the image processing step compresses a hue reproduction angle more greatly in a flesh color area of human image data, compared with still life image data.

44. The image processing method of claim 24, wherein the image processing section conducts scene discrimination and/or face image extraction, and changes a transformation condition for the image processing based on results of the scene discrimination and/or the face image extraction.

45. A program for enabling a computer to realize an image processing function to compress a hue reproduction angle in a range of flesh color area corresponding to a flesh color in the image data.

46. The program of claim 45, wherein the image processing function compresses the hue reproduction angle in a range of flesh color area such that the range of flesh color area is converged to a target hue reproduction angle specified as a target.

47. The program of claim 45, wherein the image processing function changes a center of a compressed hue reproduction angle in a range of the flesh color area and/or an amount of compression, based on a color temperature and a white point of illumination light at image data generation.

48. The program of claim 45, wherein the image processing function enhances a degree of the compression of the hue reproduction angle as an angle of the image data recedes from the target hue reproduction angle, in the case of converging the range of the flesh color area to the target hue reproduction angle determined specifically.

49. The program of claim 45, wherein, the image processing function decreases a degree of compression of the hue reproduction angle as chroma of the image data becomes higher.

50. A program for enabling a computer to realize an image processing function to make a contrast of neutral color image data to be low contrast, and make a contrast of chromatic color image data to be high contrast.

51. The program of claim 50, wherein the image processing function makes a difference between the contrast of chromatic color image data and the contrast of neutral color image data to be 5% or more.

52. The program of claim 50, wherein the image processing function emphasizes chroma of the image data more as lightness of the image data becomes lower.

53. The program of claim 50, wherein the image processing function increases a degree of chroma emphasis for the image data as chroma of the image data becomes greater.

54. The program of claim 50, wherein the image processing function increases a degree of chroma emphasis for the image data depending on an amount of changes in lightness of the image data.

55. The program of claim 50, wherein the image processing function lowers maximum lightness of the image data after image processing to be lower than maximum lightness of the image data before image processing.

56. The program of claim 50, wherein the image processing function compresses a hue reproduction angle in a range of a flesh color area corresponding to a flesh color in the image data.

57. The program of claim 45, wherein the image data to be subjected to the image processing are scene-referred data in the course of photographing and/or RAW data.

58. A program for enabling a computer to realize an image processing function to lower maximum lightness of image data for a reflection-type print formed through subtractive color mixing, compared to image data for a transmission-type film formed through additive color mixture or for a visible image on a monitor.

59. The program of claim 45, wherein the image processing function transforms image data subjected to the image processing into output color image signals based on characteristics of an image outputting section.

60. The program of claim 45, wherein the image processing function comprises:
a first transform function to transform input color image signals of the image data into signals in a standard color space based on characteristics of an image inputting section;
a second transform function to transform the signals in the standard color space based on characteristics of an image outputting section; and
a third transform function to transform signals in the standard color space having been transformed by the second transform function into output color image signals.

61. The program of claim 45, wherein the image processing function conducts image processing based on a color reproduction range of an output system of the image data so that the image processing causes no saturation of chroma changes by using a broader color gamut than a color gamut of the image data before image processing.

62. The program of claim 45, wherein the image processing function conducts image processing on the image data which holds a profile of an image inputting section.

63. The program of claim 45, wherein the image processing function conducts image processing on the image data for outputting on a silver halide medium.

64. The program of claim 45, wherein the image processing function compresses a hue reproduction angle more greatly in a flesh color area of human image data, compared with still life image data.

65. The program of claim 45, wherein the image processing function conducts scene discrimination and/or face image extraction, and changes a transformation condition for the image processing based on results of the scene discrimination and/or the face image extraction.
